(19) United States
(12) Patent Application Publication
(10) Pub. No.: US 2023/0215901 A1
(43) Pub. Date: Jul. 6, 2023

(54) SOLID-STATE IMAGING ELEMENT

(71) Applicant: SONY SEMICONDUCTOR SOLUTIONS CORPORATION, Kanagawa (JP)

(72) Inventors: Kazuyoshi YAMASHITA, Kanagawa (JP); Yoshiaki MASUDA, Kanagawa (JP); Shinichiro KURIHARA, Kanagawa (JP); Syogo KUROGI, Kumamoto (JP); Yusuke UESAKA, Kanagawa (JP); Toshiki SAKAMOTO, Kumamoto (JP); Hiroyuki KAWANO, Kumamoto (JP); Masatoshi IWAMOTO, Kumamoto (JP); Takashi TERADA, Kumamoto (JP); Sintaro NAKAJIKI, Kumamoto (JP)

(73) Assignee: SONY SEMICONDUCTOR SOLUTIONS CORPORATION, Kanagawa (JP)

(21) Appl. No.: 17/996,036

(22) PCT Filed: Apr. 12, 2021
(86) PCT No.: PCT/JP2021/015170

§ 371 Date: Oct. 12, 2022

(30) Foreign Application Priority Data
Apr. 20, 2020 (JP) 2020-075051

(51) Int. Cl. H01L 27/146

(52) U.S. Cl. CPC H01L 27/14641; H01L 27/14645; H01L 27/14649; H01L 27/1463

(57) ABSTRACT

A solid-state imaging element that includes a semiconductor layer, a floating diffusion region (FD), a penetrating pixel separation region, and a non-penetrating pixel separation region. In the semiconductor layer, a visible-light pixel (PDc) that receives visible light and an infrared-light pixel (PDw) that receives infrared light are two-dimensionally arranged. The floating diffusion region is provided in the semiconductor layer and is shared by adjacent visible-light and infrared-light pixels. The penetrating pixel separation region is provided in a region excluding a region corresponding to the floating diffusion region in an inter-pixel region of the visible-light pixel and the infrared-light pixel, and penetrates the semiconductor layer in a depth direction. The non-penetrating pixel separation region is provided in the region corresponding to the floating diffusion region in the inter-pixel region, and reaches a midway part in the depth direction from the light receiving surface of the semiconductor layer.

### FIELD

The present disclosure relates to a solid-state imaging element.

### BACKGROUND

There is a solid-state imaging element that enables miniaturization by sharing a floating diffusion region by a plurality of light receiving pixels adjacent to each other in a semiconductor layer in which the plurality of light receiving pixels that receives visible light and performs photoelectric conversion is two-dimensionally arranged (for example, Patent Literature 1).

### CITATION LIST

### Patent Literature

Patent Literature 1: WO 2017/187957 A

### SUMMARY

### Technical Problem

However, in a solid-state imaging element including a light receiving pixel that receives visible light and a light receiving pixel that receives infrared light, miniaturization has been difficult.

Therefore, the present disclosure proposes a solid-state imaging element that includes a light receiving pixel receiving visible light and a light receiving pixel receiving infrared light, and can be miniaturized.

### Solution to Problem

According to the present disclosure, a solid-state imaging element is provided. The solid-state imaging element includes a semiconductor layer, a floating diffusion region, a penetrating pixel separation region, and a non-penetrating pixel separation region. In the semiconductor layer, a visible-light pixel that receives visible light and performs photoelectric conversion and an infrared-light pixel that receives infrared light and performs photoelectric conversion are two-dimensionally arranged. The floating diffusion region is provided in the semiconductor layer and is shared by the visible-light pixel and the infrared-light pixel adjacent to each other. The penetrating pixel separation region is provided in a region excluding a region corresponding to the floating diffusion region in an inter-pixel region of the visible-light pixel and the infrared-light pixel, and penetrates the semiconductor layer in a depth direction. The non-penetrating pixel separation region is provided in the region corresponding to the floating diffusion region in the inter-pixel region, and reaches a midway part in the depth direction from the light receiving surface of the semiconductor layer.

### BRIEF DESCRIPTION OF DRAWINGS

FIG. 1 is a system configuration diagram illustrating a schematic configuration example of a solid-state imaging element according to an embodiment of the present disclosure.

FIG. 2 is a plan view illustrating an example of a pixel array unit according to the embodiment of the present disclosure.

FIG. 3 is a plan view illustrating another example of the pixel array unit according to the embodiment of the present disclosure.

FIG. 4 is a cross-sectional view schematically illustrating a structure of the pixel array unit according to the embodiment of the present disclosure.

FIG. 5A is a plan view of a pixel array unit according to Example 1 of the present disclosure.

FIG. 5B is a cross-sectional view taken along line (A)-(B) of the pixel array unit according to Example 1

FIG. 5C is a cross-sectional view taken along line (C)-(D) of the pixel array unit according to Example 1 of the present disclosure.

FIG. 6A is a plan view of a pixel array unit according to Example 2 of the present disclosure.

FIG. 6B is a cross-sectional view taken along line (A)-(B) of the pixel array unit according to Example 2 of the present disclosure.

FIG. 6C is a cross-sectional view taken along line (C)-(D) of the pixel array unit according to Example 2 of the present disclosure.

FIG. 7A is a plan view of a pixel array unit according to Example 3 of the present disclosure.

FIG. 7B is a cross-sectional view taken along line (A)-(B) of the pixel array unit according to Example 3 of the present disclosure.

FIG. 8A is a plan view of a pixel array unit according to Example 4 of the present disclosure.

FIG. 8B is a cross-sectional view taken along line (C)-(D) of the pixel array unit according to Example 4 of the present disclosure.

FIG. 8C is a cross-sectional view taken along line (E)-(F) of the pixel array unit according to Example 4 of the present disclosure.

FIG. 9A is a plan view of a pixel array unit according to Example 5 of the present disclosure.

FIG. 9B is a cross-sectional view taken along line (A)-(B) of the pixel array unit according to Example 5 of the present disclosure.

FIG. 10 is a plan view of a pixel array unit according to Example 6 of the present disclosure.

FIG. 11 is a plan view of a pixel array unit according to Example 7 of the present disclosure.

FIG. 12 is a plan view of a pixel array unit according to Example 8 of the present disclosure.

FIG. 13 is a plan view of a pixel array unit according to Example 9 of the present disclosure.

FIG. 14 is a plan view of a pixel array unit according to Example 10 of the present disclosure.

FIG. 15 is a plan view of a pixel array unit according to Example 11 of the present disclosure.

FIG. 16A is a plan view of a pixel array unit according to Example 12 of the present disclosure.

FIG. 16B is a cross-sectional view taken along line (A)-(B) of the pixel array unit according to Example 12 of the present disclosure.

FIG. 17 is a plan view of a pixel array unit according to Example 13 of the present disclosure.

FIG. 18 is a plan view of a pixel array unit according to Example 14 of the present disclosure.

FIG. 19 is a plan view of a pixel array unit according to Example 15 of the present disclosure.

FIG. 20A is a plan view of a pixel array unit according to Example 16 of the present disclosure.

FIG. 20B is a cross-sectional view taken along line (A)-(B) of the pixel array unit according to Example 16 of the present disclosure.

FIG. 20C is a plan view of the pixel array unit according to Example 16 of the present disclosure.

FIG. 21A is a plan view of a pixel array unit according to Example 17 of the present disclosure.

FIG. 21B is a cross-sectional view taken along line (A)-(B) of the pixel array unit according to Example 17 of the present disclosure.

FIG. 21C is a plan view of the pixel array unit according to Example 17 of the present disclosure.

FIG. 22 is an explanatory diagram of a pixel array unit according to Example 18 of the present disclosure.

FIG. 23 is a cross-sectional view schematically illustrating a structure of the pixel array unit according to Modification 1 of the embodiment of the present disclosure.

FIG. 24 is a cross-sectional view schematically illustrating a structure of the pixel array unit according to Modification 2 of the embodiment of the present disclosure.

FIG. 25 is a cross-sectional view schematically illustrating a structure of the pixel array unit according to Modification 3 of the embodiment of the present disclosure.

FIG. 26 is a diagram illustrating an example of spectral characteristic of an IR cut filter according to the embodiment of the present disclosure.

FIG. 27 is a graph illustrating an example of spectral characteristic of each unit pixel according to the embodiment of the present disclosure.

FIG. 28 is a diagram illustrating an example of a coloring material of the IR cut filter according to the embodiment of the present disclosure.

FIG. 29 is a diagram illustrating another example of spectral characteristic of the IR cut filter according to the embodiment of the present disclosure.

FIG. 30 is a diagram illustrating another example of spectral characteristic of the IR cut filter according to the embodiment of the present disclosure.

FIG. 31 is a diagram illustrating another example of spectral characteristic of the IR cut filter according to the embodiment of the present disclosure.

FIG. 32 is a diagram illustrating another example of spectral characteristic of the IR cut filter according to the embodiment of the present disclosure.

FIG. 33 is a cross-sectional view schematically illustrating a structure of the pixel array unit according to Modification 4 of the embodiment of the present disclosure.

FIG. 34 is a cross-sectional view schematically illustrating a structure of the pixel array unit according to Modification 5 of the embodiment of the present disclosure.

FIG. 35 is a cross-sectional view schematically illustrating a structure of the pixel array unit according to Modification 6 of the embodiment of the present disclosure.

FIG. 36 is a cross-sectional view schematically illustrating a structure of the pixel array unit according to Modification 7 of the embodiment of the present disclosure.

FIG. 37 is a cross-sectional view schematically illustrating a structure of the pixel array unit according to Modification 8 of the embodiment of the present disclosure.

FIG. 38 is a cross-sectional view schematically illustrating a structure of the pixel array unit according to Modification 9 of the embodiment of the present disclosure.

FIG. 39 is a cross-sectional view schematically illustrating a peripheral structure of the solid-state imaging element according to the embodiment of the present disclosure.

FIG. 40 is a diagram illustrating a planar configuration of the solid-state imaging element according to the embodiment of the present disclosure.

FIG. 41 is a block diagram illustrating a configuration example of an imaging apparatus as an electronic apparatus to which the technology according to the present disclosure is applied.

FIG. 42 is a graph illustrating a relationship between a cell size and a color mixing ratio in a pixel array unit of a reference example.

### DESCRIPTION OF EMBODIMENTS

Hereinafter, embodiments of the present disclosure will be described with reference to the drawings. In each of the following embodiments, same parts are given the same reference signs to omit redundant description.

In recent years, a solid-state imaging element capable of simultaneously acquiring a visible light image and an infrared image has been known. In this solid-state imaging element, a light receiving pixel that receives visible light and a light receiving pixel that receives infrared light are formed side by side in a same pixel array unit.

However, when a visible-light receiving pixel and an infrared-light receiving pixel are formed in the same pixel array unit, the infrared light entering the infrared-light receiving pixel may leak to an adjacent light receiving pixel, and color mixing may occur in the adjacent light receiving pixel.

Since the infrared light has a longer wavelength than the visible light and thus has a longer optical path length, the infrared light passing through a photodiode is reflected by a lower wiring layer and tends to leak into the adjacent light receiving pixel.

Here, a definition of the pixel according to the present disclosure will be described. When the pixel array unit in which pixels having a square planar shape are arranged in a matrix, there are a pixel array unit in which an on-chip lens is provided in each pixel, a pixel array unit in which one on-chip lens is provided in two adjacent pixels, a pixel array unit in which one on-chip lens is provided in four pixels adjacent in a matrix direction, and a pixel array unit in which one color filter is provided in four pixels adjacent in the matrix direction. In these pixel array units, one pixel is defined as a single pixel, and a length of one side of the single pixel in a plan view is defined as a cell size.

Furthermore, for example, when a pixel having a square planar shape is separated into two divided pixels having an equal area and a rectangular planar shape, a pixel combining two divided pixels to form the square planar shape is defined as a single pixel, and a length of one side of the single pixel in plan view is defined as a cell size.

Furthermore, depending on a solid-state imaging element 1, for example, there is a pixel array unit in which two types of pixels with different sizes are alternately and two-dimensionally arranged. In this case, for each of a large pixel and a small pixel, a pixel having the shortest distance between opposing sides is defined as a fine pixel.

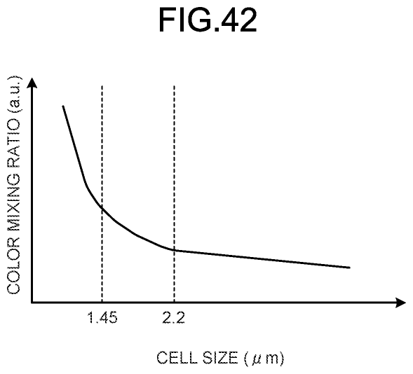

Here, in a pixel array unit 10 according to an embodiment, the cell size is preferably 2.2 (μm) or less. More preferably, the pixel array unit 10 desirably has the cell size of 1.45 (μm) or less. FIG. 42 is a diagram illustrating a relationship between the cell size and a color mixing ratio in a pixel array unit of a reference example.

As illustrated in FIG. 42, in the pixel array unit of the reference example, the color mixing ratio greatly increases when the cell size is 2.2 (μm) or less, and the color mixing further sharply increases when the cell size is 1.45 (μm) or less. In other words, in the pixel array unit of the reference example, when the cell size is reduced to a range of 2.2 (μm) or less and further to 1.45 (μm) or less, the color mixing sharply increases. Thus, it is extremely difficult to miniaturize the pixel array unit.

The pixel array unit 10 according to the embodiment can suppress an occurrence of color mixing by employing a configuration described below, and is therefore possible to acquire an image having no problem in practical use even when the cell size is reduced to 2.2 (μm) or less, and further to 1.45 (μm) or less.

<Configuration of Solid-State Imaging Element>

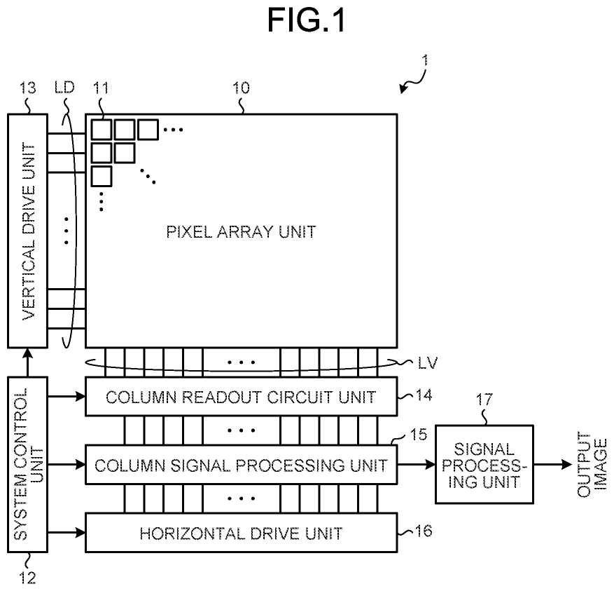

FIG. 1 is a system configuration diagram illustrating a schematic configuration example of the solid-state imaging element 1 according to the embodiment of the present disclosure. As illustrated in FIG. 1, the solid-state imaging element 1 that is a CMOS image sensor includes the pixel array unit 10, a system control unit 12, a vertical drive unit 13, a column readout circuit unit 14, a column signal processing unit 15, a horizontal drive unit 16, and a signal processing unit 17.

The pixel array unit 10, the system control unit 12, the vertical drive unit 13, the column readout circuit unit 14, the column signal processing unit 15, the horizontal drive unit 16, and the signal processing unit 17 are provided on a same semiconductor substrate or on a plurality of laminated semiconductor substrates that are electrically connected.

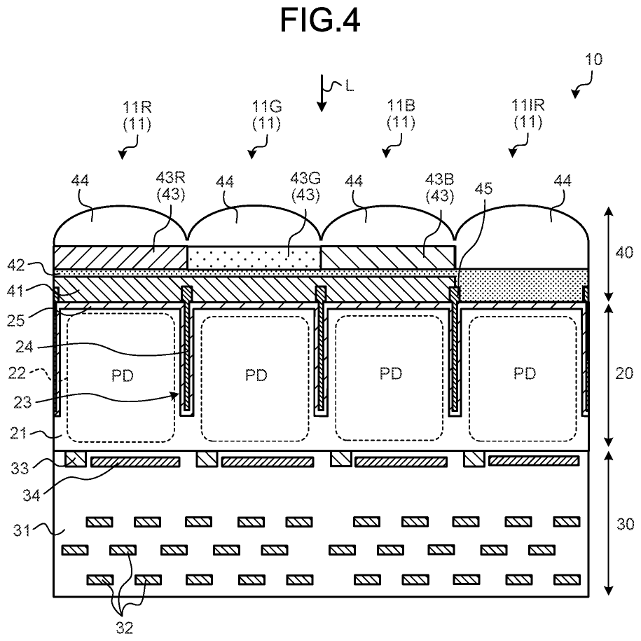

In the pixel array unit 10, an effective unit pixel (hereinafter also referred to as “unit pixel”) 11 has a photoelectric conversion element (e.g., photodiode PD (see FIG. 4)) capable of photoelectrically converting a charge amount corresponding to an incident light amount, accumulating the charge amount therein, and outputting the charge amount as a signal, and effective unit pixels are two-dimensionally arranged in a matrix.

Furthermore, in addition to the effective unit pixel 11, the pixel array unit 10 may include a region in which a dummy unit pixel having a structure without the photodiode PD or the like, a light-shielding unit pixel in which light entering from outside is blocked by shielding a light receiving surface, or the like is arranged in a row and/or column.

Note that the light-shielding unit pixel may have the same configuration as the effective unit pixel 11 except for a light-shielding structure of the light receiving surface. Furthermore, in the following description, a photocharge of the charge amount according to the incident light amount is also simply referred to as a “charge”, and the unit pixel 11 may also be simply referred to as a “pixel”.

In the pixel array unit 10, a pixel drive line LD is formed for each row in a left-right direction in the drawing (pixel array direction of a pixel row) with respect to the pixel array in a matrix, and a vertical pixel wiring LV is formed for each column in a top-bottom direction in the drawing (pixel array direction of a pixel column). One end of the pixel drive line LD is connected to an output terminal corresponding to each row of the vertical drive unit 13.

The column readout circuit unit 14 includes at least a circuit that supplies a constant current to the unit pixel 11 for each column in a selected row in the pixel array unit 10, a current mirror circuit, and a switch to change the unit pixel 11 to be read.

The column readout circuit unit 14 configures an amplifier together with a transistor in the selected pixel in the pixel array unit 10, converts a photocharge signal into a voltage signal, and outputs the voltage signal to the vertical pixel wiring LV.

The vertical drive unit 13 includes a shift register and an address decoder, and drives each unit pixel 11 of the pixel array unit 10 at the same time for all pixels or in units of rows. Although a specific configuration is not illustrated, the vertical drive unit 13 has a configuration including a readout scanning system and a sweep scanning system or a batch sweep and batch transfer system.

In order to read a pixel signal from the unit pixel 11, the readout scanning system sequentially selects and scans the unit pixel 11 in the pixel array unit 10 row by row. In the case of row driving (rolling shutter operation), sweep scanning is performed on a read row on which readout scanning is performed by the readout scanning system earlier than the read scanning by time corresponding to a shutter speed.

In addition, in the case of global exposure (global shutter operation), batch sweeping is performed earlier than batch transfer by the time corresponding to the shutter speed. The sweeping sweeps (resets) unnecessary charges from the photodiodes PD and the like in the unit pixels 11 of the read row. Then, a so-called electronic shutter operation is performed by sweeping (resetting) unnecessary charges.

Here, the electronic shutter operation refers to an operation of discarding unnecessary photocharges accumulated in the photodiodes PD or the like until immediately before and newly starting exposure (starting accumulation of photocharges).

The signal read by the read operation by the readout scanning system corresponds to the incident light amount after the immediately preceding read operation or the electronic shutter operation. In the case of row driving, a period from the read timing by the immediately preceding read operation or the sweep timing by the electronic shutter operation to the read timing by the current read operation is a photocharge accumulation time (exposure time) in the unit pixel 11. In the case of global exposure, time from batch sweeping to batch transfer is the accumulation time (exposure time).

The pixel signal is output from each unit pixel 11 in the pixel row selectively scanned by the vertical drive unit 13, and supplied to the column signal processing unit 15 through each of the vertical pixel wirings LV. The column signal processing unit 15 performs predetermined signal processing, for each pixel column of the pixel array unit 10, on the pixel signal output from each unit pixel 11 in the selected row through the vertical pixel wiring LV, and temporarily holds the pixel signal after the signal processing.

Specifically, the column signal processing unit 15 performs at least a noise removal process such as a correlated double sampling (CDS) process as signal processing. The CDS processing by the column signal processing unit 15 removes fixed pattern noise unique to pixels such as reset noise and threshold variation of an amplification transistor AMP.

Note that the column signal processing unit 15 can be configured to have, for example, an AD conversion function in addition to the noise removal process, and output the pixel signal as a digital signal.

The horizontal drive unit 16 includes a shift register and an address decoder, and sequentially selects a unit circuit corresponding to a pixel column of the column signal processing unit 15. Selective scanning by the horizontal drive unit 16 sequentially outputs the pixel signals subjected to the signal processing by the column signal processing unit 15 to the signal processing unit 17.

The system control unit 12 includes a timing generator that generates various timing signals, and performs drive control of the vertical drive unit 13, the column signal processing unit 15, the horizontal drive unit 16, and the like based on various timing signals generated by the timing generator.

The solid-state imaging element 1 further includes the signal processing unit 17 and a data storage unit (not illustrated). The signal processing unit 17 has at least an addition processing function, and performs various types of signal processing such as an addition process on the pixel signal output from the column signal processing unit 15.

The data storage unit temporarily stores data necessary for signal processing in the signal processing unit 17. The signal processing unit 17 and the data storage unit may be an external signal processing unit provided on a substrate different from the solid-state imaging element 1, such as a digital signal processor (DSP) or software, or may be mounted on the same substrate as the solid-state imaging element 1.

<Configuration of Pixel Array Unit>

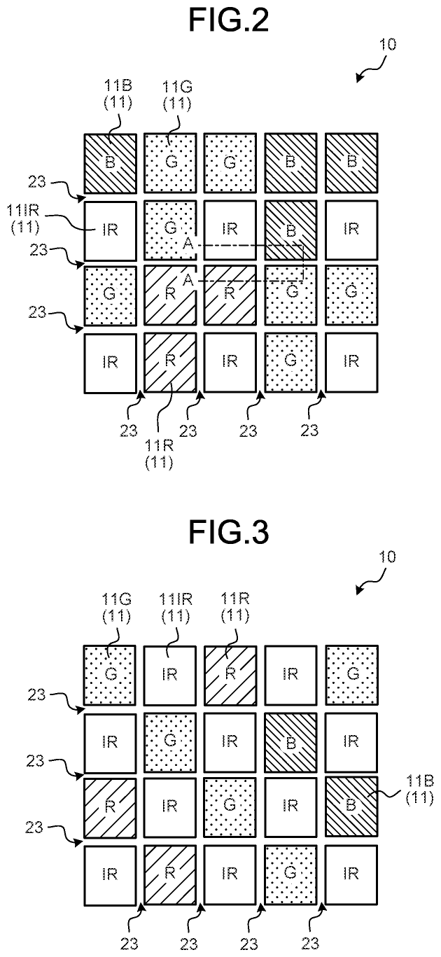

Next, a detailed configuration of the pixel array unit 10 will be described with reference to FIGS. 2 to 4. FIG. 2 is a plan view illustrating an example of the pixel array unit 10 according to the embodiment of the present disclosure.

As illustrated in FIG. 2, in the pixel array unit 10 according to the embodiment, a plurality of unit pixels 11 are arranged in a matrix. The plurality of unit pixels 11 includes an R pixel 11R that receives red light, a G pixel 11G that receives green light, a B pixel 11B that receives blue light, and an IR pixel 11IR that receives infrared light.

The R pixel 11R, the G pixel 11G, and the B pixel 11B are examples of first light receiving pixels, and are also collectively referred to as a “visible-light pixel” below. Furthermore, the IR pixel 11IR is also referred to as an “infrared-light pixel” or “visible-light pixel”.

Furthermore, a pixel separation region 23 is provided between adjacent unit pixels 11. The pixel separation regions 23 are arranged in a lattice planar shape in the pixel array unit 10.

In the pixel array unit 10 according to the embodiment, for example, as illustrated in FIG. 2, the visible-light pixels of the same type may be arranged in an L shape, and the IR pixels 11IR may be arranged in the remaining portions.

Note that the arrangement of the visible-light pixels and the IR pixels 11IR in the pixel array unit 10 is not limited to the example in FIG. 2. For example, as illustrated in FIG. 3, the IR pixels 11IR may be arranged in a checkered pattern, and three types of visible-light pixels may be arranged in the remaining portions. FIG. 3 is a plan view illustrating another example of the pixel array unit 10 according to the embodiment of the present disclosure.

FIG. 4 is a cross-sectional view schematically illustrating a structure of the pixel array unit 10 according to the embodiment of the present disclosure, and is a view corresponding to a cross-sectional view taken along line A-A in FIG. 2.

As illustrated in FIG. 4, the pixel array unit 10 according to the embodiment includes a semiconductor layer 20, a wiring layer 30, and an optical layer 40. Then, in the pixel array unit 10, the optical layer 40, the semiconductor layer 20, and the wiring layer 30 are laminated in this order from a side on which light L from outside enters (hereinafter also referred to as a “light incident side”).

The semiconductor layer 20 includes a semiconductor region 21 of a first conductivity type (e.g., P-type) and a semiconductor region 22 of a second conductivity type (e.g., N-type). Then, in the semiconductor region 21 of the first conductivity type, the semiconductor region 22 of the second conductivity type is formed in units of pixels, thereby forming the photodiode PD by PN junction. The photodiode PD is an example of a photoelectric conversion unit.

Furthermore, the semiconductor layer 20 is provided with the pixel separation region 23 described above. The pixel separation region 23 separates the photodiodes PD of the unit pixels 11 adjacent to each other. Furthermore, the pixel separation region 23 is provided with a light shielding wall 24 and a metal oxide film 25.

The light shielding wall 24 is a wall-shaped film that is provided along the pixel separation region 23 in plan view, and shields light obliquely entering from the adjacent unit pixel 11. By providing the light shielding wall 24, it is possible to suppress entry of light transmitted through the adjacent unit pixel 11, thereby suppressing color mixing.

The light shielding wall 24 is made of a material having a light shielding property, such as various metals (tungsten, aluminum, silver, copper, and alloy thereof) and a black organic film. Furthermore, in the embodiment, the light shielding wall 24 does not penetrate the semiconductor layer 20, and extends from a surface of the semiconductor layer 20 on the light incident side to a middle of the semiconductor layer 20.

The metal oxide film 25 is provided so as to cover the light shielding wall 24 in the pixel separation region 23. The metal oxide film 25 is also provided so as to cover a surface of the semiconductor region 21 on the light incident side. The metal oxide film 25 is configured with, for example, a material having a fixed charge (e.g., hafnium oxide, tantalum oxide, and aluminum oxide).

In the embodiment, an antireflection film, an insulating film, or the like may be separately provided between the metal oxide film 25 and the light shielding wall 24.

The wiring layer 30 is disposed on a surface of the semiconductor layer 20 opposite to the light incident side. The wiring layer 30 is configured by forming a plurality of layers of wiring 32 and a plurality of pixel transistors 33 in an interlayer insulating film 31. The plurality of pixel transistors 33 performs reading of the charges accumulated in the photodiodes PD, and the like.

In addition, the wiring layer 30 according to the embodiment further includes a metal layer 34 configured with metal containing tungsten as a main component. The metal layer 34 is provided on the light incident side of the plurality of layers of wiring 32 in each unit pixel 11.

The optical layer 40 is disposed on a surface of the semiconductor layer 20 on the light incident side (hereinafter also referred to as a “light receiving surface”). The optical layer 40 includes an IR cut filter 41, a planarization film 42, a color filter 43, and an on-chip lens (OCL) 44.

The IR cut filter 41 is formed of an organic material to which a near infrared absorbing dye is added as an organic coloring material. The IR cut filter 41 is arranged on a surface of the semiconductor layer 20 on the light incident side in the visible-light pixel (R pixel 11R, G pixel 11G, and B pixel 11B), and is not arranged on the surface of the semiconductor layer 20 on the light incident side in the infrared-light pixel (IR pixel 11IR). The IR cut filter 41 will be detailed later.

The planarization film 42 is provided to planarize the surface on which the color filter 43 and the OCL 44 are formed and to avoid unevenness generated in a rotary coating process when the color filter 43 and the OCL 44 are formed.

The planarization film 42 is formed of, for example, an organic material (e.g., acrylic resin). Note that the planarization film 42 is not limited to being formed of the organic material, and may be formed of silicon oxide, silicon nitride, or the like.

Furthermore, as described above, since the IR cut filter 41 is not provided in the IR pixel 11IR, the planarization film 42 is in direct contact with the metal oxide film 25 of the semiconductor layer 20 in the IR pixel 11IR.

The color filter 43 is an optical filter that transmits light of a predetermined wavelength in the light L condensed by the OCL 44. The color filter 43 is arranged on a surface of the planarization film 42 on the light incident side in the visible-light pixel (R pixel 11R, G pixel 11G, and B pixel 11B).

The color filter 43 includes, for example, a color filter 43R that transmits red light, a color filter 43G that transmits green light, and a color filter 43B that transmits blue light.

In the embodiment, the color filter 43R is provided in the R pixel 11R, the color filter 43G is provided in the G pixel 11G, and the color filter 43B is provided in the B pixel 11B. Furthermore, in the embodiment, the color filter 43 is not arranged in the infrared-light pixel (IR pixel 11IR).

The OCL 44 is a lens that is provided in each unit pixel 11 and condenses the light L on the photodiode PD of each unit pixel 11. The OCL 44 is configured with, for example, an acrylic resin. Furthermore, as described above, since the color filter 43 is not provided in the infrared-light pixel (IR pixel 11IR), the OCL 44 is in direct contact with the planarization film 42 in the infrared-light pixel (IR pixel 11IR).

Furthermore, in an interface between the IR cut filter 41 or the planarization film 42 and the semiconductor layer 20, a light shielding wall 45 is provided at a position corresponding to the pixel separation region 23. The light shielding wall 45 is a wall-shaped film that shields light obliquely entering from the adjacent unit pixel 11, and is provided so as to continue from the light shielding wall 24.

It is possible to suppress entry of light transmitted through the IR cut filter 41 and the planarization film 42 of the adjacent unit pixel 11 by providing the light shielding wall 45. Thus, the color mixing can be suppressed. The light shielding wall 45 is configured with, for example, aluminum, tungsten, or the like.

Furthermore, in the example illustrated in FIG. 4, the pixel separation region 23 extends from the light receiving surface of the semiconductor layer 20 to a midway part in a depth direction. However, this is an example, and various configurations are applicable. As described above, the infrared light has a longer wavelength than the visible light and thus has a longer optical path length. When the infrared light enters in an oblique direction, for example, the infrared light may be transmitted to a deep position in the photodiode PD and leak into the adjacent photodiode PD to cause color mixing.

Therefore, from the viewpoint of preventing the color mixing, the pixel separation region 23 is preferably configured to penetrate the front and back of the semiconductor layer 20. However, in this configuration, each light receiving pixel is optically separated from an adjacent light receiving pixel, and is also electrically separated. Therefore, it is necessary to provide the pixel transistor 33 and a floating diffusion region. As a result, miniaturization becomes difficult.

On the other hand, in the configuration illustrated in FIG. 4, the pixel transistor 33 and the floating diffusion region can be provided immediately below the pixel separation region 23 in an inter-pixel region of the visible-light pixel and the infrared-light pixel. As a result, since the visible-light pixel and infrared-light pixel adjacent to each other can share the pixel transistor 33 and the floating diffusion region, miniaturization is possible but the aforementioned problem of color mixing remains.

Therefore, the pixel array unit 10 according to the present disclosure includes the pixel separation regions 23 having different depths in the inter-pixel regions of the visible-light pixel and the infrared-light pixel, thereby enabling miniaturization while suppressing the color mixing.

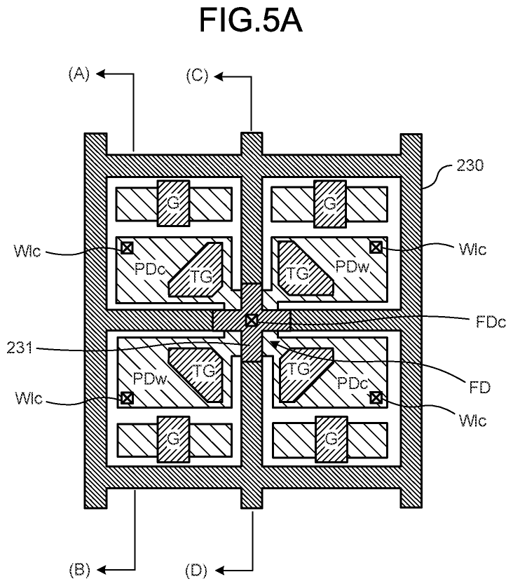

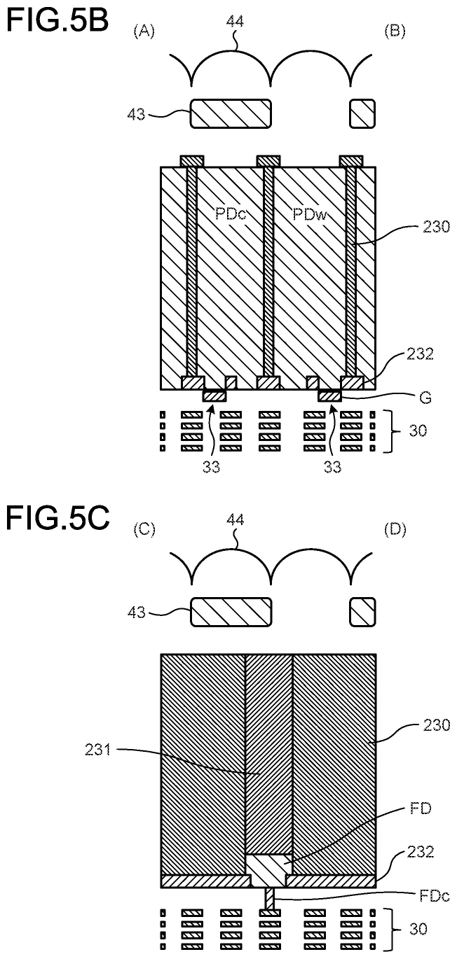

Hereinafter, examples of the pixel separation region 23 according to the present disclosure will be described with reference to FIGS. 5A to 22. In FIGS. 5A to 15, a plan view illustrates a portion of four adjacent pixels in the matrix direction, and a cross-sectional view illustrates a portion of two adjacent pixels.

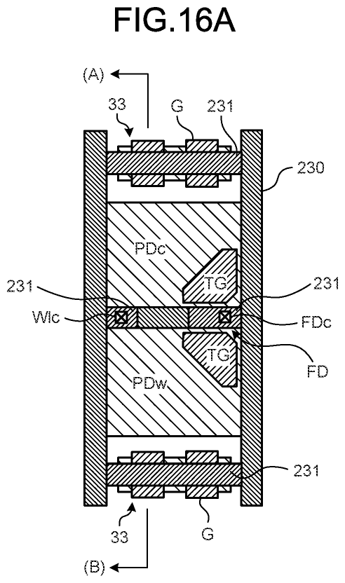

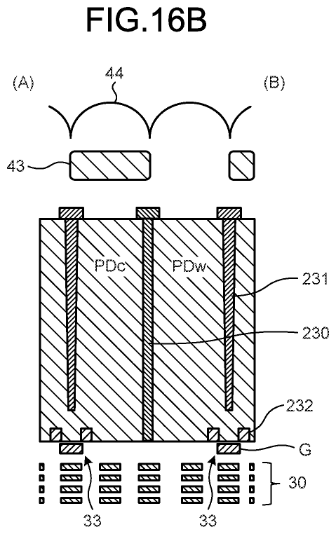

Furthermore, FIGS. 16 to 22 illustrate a portion of two adjacent pixels. Note that, here, the visible-light pixel is referred to as a visible-light pixel PDc, the infrared-light pixel as an infrared-light pixel PDw, a gate of the pixel transistor 33 as a gate G, a well contact as a well contact Wlc, and a transfer gate as a TG.

### Example 1

FIG. 5A is a plan view of a pixel array unit according to Example 1 of the present disclosure. FIG. 5B is a cross-sectional view taken along line (A)-(B) of the pixel array unit according to Example 1 of the present disclosure. FIG. 5C is a cross-sectional view taken along line (C)-(D) of the pixel array unit according to Example 1 of the present disclosure.

As illustrated in FIG. 5A, in the pixel array unit according to Example 1, a floating diffusion region FD is provided at the center of four pixels adjacent in the matrix direction. The floating diffusion region is provided by forming an impurity region on the semiconductor substrate. A floating diffusion region contact FDc for reading a transferred charge is connected to the floating diffusion region FD. The floating diffusion contact FDc is further connected to the wiring 32 in the wiring layer 30, and the wiring is connected to the amplification transistor.

Among the four pixels, two visible-light pixels PDc are adjacent to each other on a diagonal line. Still more, two infrared-light pixels PDw are adjacent to each other on a diagonal line. The well contact Wlc is provided in each of the visible-light pixels PDc and the infrared-light pixels PDw.

The well contact Wlc is grounded. As a result, a potential of the substrate on which the semiconductor layer 20 is provided is maintained at 0 (V). In addition, the well contacts Wlc are uniformly arranged in a plane direction of the semiconductor layer 20. As a result, variations in characteristics of each pixel are suppressed. Furthermore, the pixel transistor 33 is adjacent to each of the visible-light pixels PDc and the infrared-light pixels PDw.

In the pixel array unit, by sequentially applying a predetermined voltage to each transfer gate TG, the charge photoelectrically converted by the visible-light pixel PDc and the infrared-light pixel PDw are sequentially transferred to the floating diffusion region FD. In this manner, the floating diffusion region FD is shared by the four pixels surrounding the floating diffusion region FD.

In this pixel array unit, since the floating diffusion region FD is provided at the center of the four pixels in the inter-pixel region of the visible-light pixel PDc and the infrared-light pixel PDw, it is not possible to provide a pixel separation groove penetrating the front and back of the semiconductor layer 20. Here, the pixel separation groove refers to, for example, a trench structure provided by digging the substrate.

Therefore, in the pixel array unit according to Example 1, a deep trench part 230 is provided in a region excluding a region corresponding to the floating diffusion region FD in the inter-pixel region, and a shallow trench part 231 is provided in the region corresponding to the floating diffusion region FD.

The deep trench part 230 indicates the trench structure in which a length in the depth direction of the semiconductor layer 20 is longer (deeper) than the shallow trench part 231. The shallow trench part 231 configures a non-penetrating pixel separation region reaching the midway part in the depth direction from the light receiving surface of the semiconductor layer 20. As a result, the pixel array unit can be provided with the floating diffusion region FD at the position surrounded by four pixels adjacent in the matrix direction.

As illustrated in FIG. 5B, the deep trench part 230 extends from the light receiving surface of the semiconductor layer 20 toward a surface opposed to the light receiving surface. Still more, the deep trench part 230 is in contact with a shallow trench isolation (STI) 232 extending from the surface opposed to the light receiving surface toward the light receiving surface of the semiconductor layer 20. The deep trench part 230 and the STI 232 configure a penetrating pixel separation region that penetrates the semiconductor layer 20 in the depth direction. Here, the STI 232 is, for example, an element isolation structure provided to isolate active regions between elements such as transistors.

As a result, in the pixel array unit according to Example 1, since the region excluding the region corresponding to the floating diffusion region FD in the inter-pixel region is shielded by the penetrating pixel separation region, it is possible to suppress the occurrence of color mixing even when the infrared light is transmitted deeply in the semiconductor layer 20.

On the other hand, as illustrated in FIG. 5C, the shallow trench part 231 reaches the floating diffusion region FD from the light receiving surface of the semiconductor layer 20, and the floating diffusion region FD is provided immediately below the shallow trench part 231. As described above, in the pixel array unit according to Example 1, the floating diffusion region FD shared by the four pixels can be provided at the center of the four pixels adjacent in the matrix direction in the semiconductor layer 20.

As a result, in the pixel array unit according to Example 1, the pixels can be miniaturized as compared with a case where the floating diffusion region FD is provided for each pixel. For example, according to the pixel array unit according to Example 1, even when the shortest distance between sides of the visible-light pixel PDc and the infrared-light pixel PDw facing each other in plan view is reduced to 2.2 microns or less, an occurrence rate of color mixing can be suppressed.

Furthermore, in the pixel array unit according to Example 1, since the light receiving areas of the visible-light pixels PDc and the infrared-light pixels PDw can be widened as compared with a case where the floating diffusion region FD is not shared, a saturation electron amount, a photoelectric conversion efficiency, a sensitivity, and an S/N ratio can be improved.

In addition, to form the deep trench part 230 and the shallow trench part 231, a shallow trench is first formed at a formation position of the deep trench part 230 by etching in a state that a mask is stacked at the formation position of the shallow trench part 231 on the light receiving surface of the semiconductor layer 20.

Then, the mask is removed from above the formation position of the shallow trench part 231, the formation position of the shallow trench part 231 and the formation position of the deep trench part 230 are simultaneously etched, and a light shielding member is embedded in the trench, thereby simultaneously forming the deep trench part 230 and the shallow trench part 231.

Here, since the etching time for forming the shallow trench part 231 is shorter than the etching time for forming the deep trench part 230, a width of the shallow trench part 231 in plan view is narrower than a width of the deep trench part 230 in plan view. As a result, the pixel array unit according to Example 1 can widen the areas of the visible-light pixels PDc and the infrared-light pixels PDw, and thus can improve the saturation electron amount, the photoelectric conversion efficiency, the sensitivity, and the S/N ratio.

### Example 2

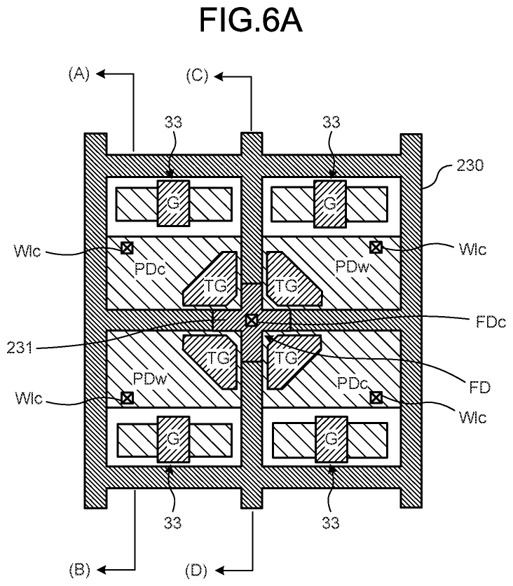

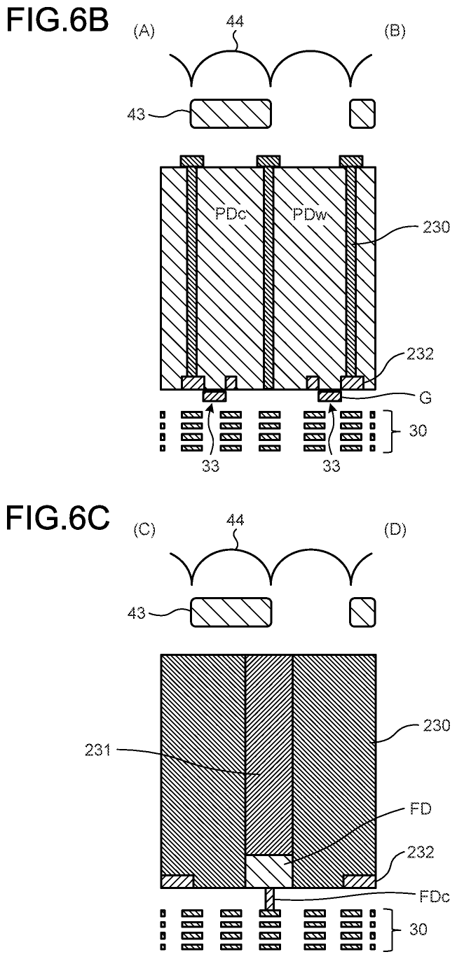

FIG. 6A is a plan view of a pixel array unit according to Example 2 of the present disclosure. FIG. 6B is a cross-sectional view taken along line (A)-(B) of the pixel array unit according to Example 2 of the present disclosure. FIG. 6C is a cross-sectional view taken along line (C)-(D) of the pixel array unit according to Example 2 of the present disclosure.

As illustrated in FIG. 6A, arrangement of each component in a plan view of the pixel array unit according to Example 2 is similar to that of the pixel array unit according to Example 1, but a cross-sectional structure is different from that of the pixel array unit according to Example 1.

As illustrated in FIGS. 6B and 6C, the deep trench part 230 according to Example 2 is different from that of Example 1 in that a portion that performs pixel separation between the visible-light pixel PDc and the infrared-light pixel PDw sharing the floating diffusion region FD penetrates the semiconductor layer 20 in the depth direction.

Also with the pixel array unit according to Example 2, similarly to Example 1, color mixing can be suppressed and miniaturization can be achieved. In addition, the areas of the visible-light pixels PDc and the infrared-light pixels PDw can be increased, and thus the saturation electron amount, the photoelectric conversion efficiency, the sensitivity, and the S/N ratio can be improved.

### Example 3

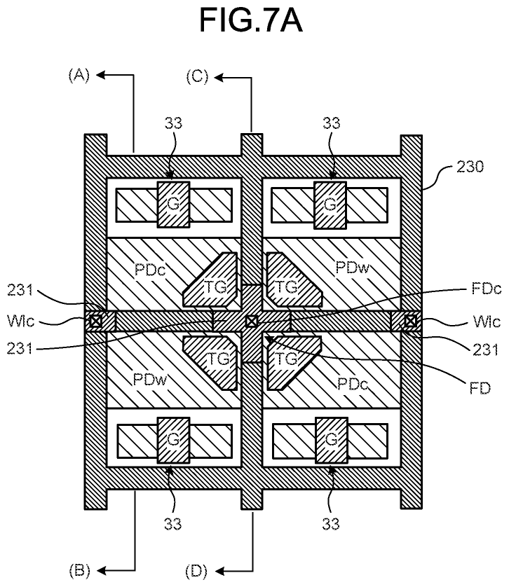

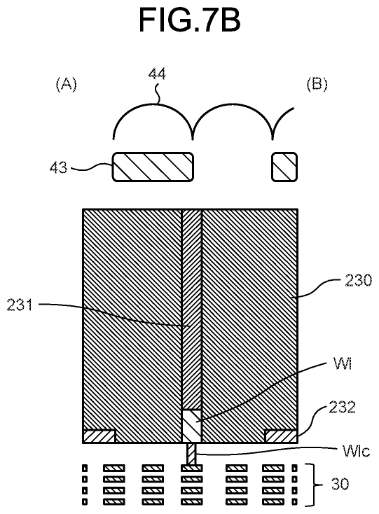

FIG. 7A is a plan view of a pixel array unit according to Example 3 of the present disclosure. FIG. 7B is a cross-sectional view taken along line (A)-(B) of the pixel array unit according to Example 3 of the present disclosure. As illustrated in FIG. 7A, in the pixel array unit according to Example 3, the well contact Wlc is provided between the visible-light pixels PDc and the infrared-light pixels PDw that share the floating diffusion region FD and unillustrated visible-light pixels PDc and infrared-light pixels PDw that are adjacent to each other. In the example illustrated in FIG. 7A, the well contact Wlc is provided between illustrated four pixels and unillustrated four pixels adjacent in the row direction.

Then, in the pixel array unit according to Example 3, the shallow trench part 231 is provided in a region corresponding to the well contact Wlc in the inter-pixel region. Other components are similar to those of the pixel array unit according to Example 2. Note that a cross section taken along line (C)-(D) of the pixel array unit illustrated in FIG. 7A has the same configuration as the cross section illustrated in FIG. 6C.

As illustrated in FIG. 7B, the shallow trench part 231 reaches the midway part in the depth direction from the light receiving surface of the semiconductor layer 20. Specifically, the shallow trench part 231 reaches, from the light receiving surface of the semiconductor layer 20, an impurity diffusion region (well region) W1 in the semiconductor layer 20 connected to the well contact Wlc.

As a result, in the pixel array unit according to Example 3, since the well contact Wlc can be shared by the four pixels surrounding the well contact Wlc, miniaturization can be performed as compared with cases where the well contact Wlc is provided for each of the visible-light pixels PDc and the infrared-light pixels PDw.

Furthermore, in the pixel array unit according to Example 3, a region where the well contact Wlc illustrated in FIG. 6A is provided can be used as a photoelectric conversion region. As a result, since the pixel array unit can widen the areas of the visible-light pixels PDc and the infrared-light pixels PDw, the saturation electron amount, the photoelectric conversion efficiency, the sensitivity, and the S/N ratio can be improved.

Furthermore, in the pixel array unit according to Example 3, since the penetrating pixel separation region by the deep trench part 230 and the STI 232 is provided in the region other than the region corresponding to the well contact Wlc and the floating diffusion region FD in the inter-pixel region, color mixing can be suppressed.

Note that the pixel array unit according to Example 3 may have a configuration in which the penetrating pixel separation region by the deep trench part 230 and the STI 232 is provided in a region other than the region corresponding to the well contact Wlc in the inter-pixel region. In this case, in the pixel array unit according to Example 3, the floating diffusion region FD is provided for each of the visible-light pixels PDc and the infrared-light pixels PDw.

Also in this pixel array unit, the well contact Wlc is shared by the four pixels surrounding the well contact Wlc, and thus miniaturization is possible accordingly. Furthermore, in the pixel array unit, the penetrating pixel separation region by the deep trench part 230 and the STI 232 is expanded. Thus, a function of suppressing the color mixing is improved.

### Example 4

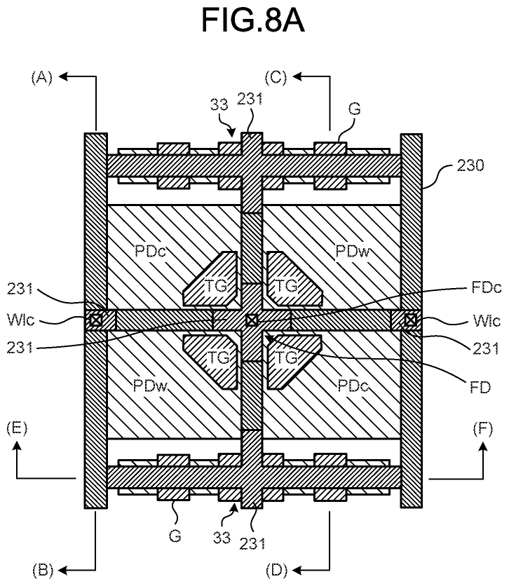

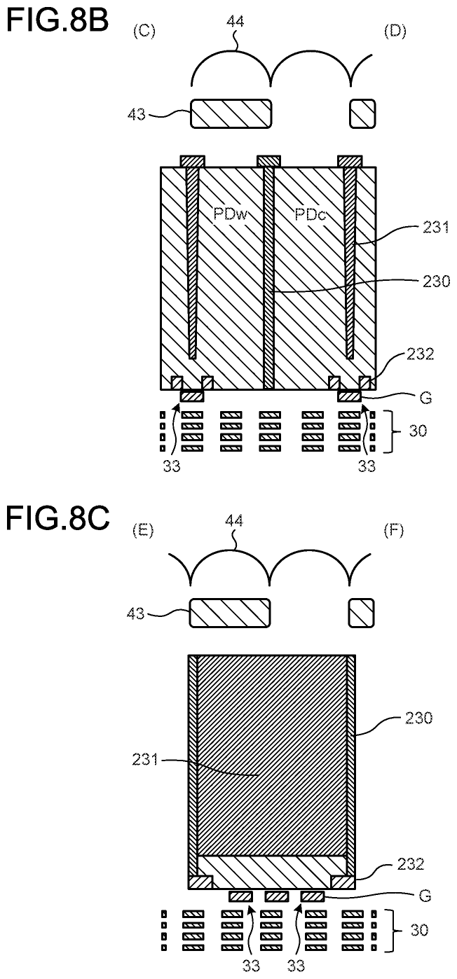

FIG. 8A is a plan view of a pixel array unit according to Example 4 of the present disclosure. FIG. 8B is a cross-sectional view taken along line (C)-(D) of the pixel array unit according to Example 4 of the present disclosure. FIG. 8C is a cross-sectional view taken along line (E)-(F) of the pixel array unit according to Example 4 of the present disclosure.

As illustrated in FIGS. 8A, 8B, and 8C, in the pixel array unit according to Example 4, the shallow trench part 231 is provided in a region corresponding to the pixel transistor 33 in the inter-pixel region. Other components are similar to those of the pixel array unit according to Example 3. Note that a cross section taken along line (A)-(B) of the pixel array unit illustrated in FIG. 8A has the same configuration as the cross section illustrated in FIG. 7B.

In the pixel array unit according to Example 4, the pixel transistor 33 can be shared by the visible-light pixel PDc and the infrared-light pixel PDw. For example, the pixel transistor 33 is shared by two pixels of the visible-light pixel PDc and the infrared-light pixel PDw that share the floating diffusion region FD illustrated in FIG. 8A.

Furthermore, the pixel transistor 33 can be shared by the visible-light pixel PDc and the infrared-light pixel PDw adjacent, in the column direction, to the four pixels illustrated in FIG. 8A. In other words, the pixel transistor 33 can be shared by four pixels provided on both sides in the column direction across the pixel transistor 33.

Note that the pixel array unit according to Example 4 may have a configuration in which the penetrating pixel separation region by the deep trench part 230 and the STI 232 is provided in a region other than the region corresponding to the pixel transistor 33 in the inter-pixel region.

In this case, in the pixel array unit according to Example 4, the floating diffusion region FD is provided for each of the visible-light pixels PDc and the infrared-light pixels PDw, and the well contact Wlc is provided for each of the visible-light pixels PDc and the infrared-light pixels PDw.

Also in this pixel array unit, the pixel transistor is shared by two adjacent pixels or four adjacent pixels in the matrix direction, and thus miniaturization is possible. Furthermore, in the pixel array unit, the penetrating pixel separation region by the deep trench part 230 and the STI 232 is expanded. Thus, a function of suppressing the color mixing is improved.

Furthermore, as illustrated in FIGS. 8A and 8C, the penetrating pixel separation region configured with the deep trench part 230 and the STI 232 in Example 4 extends to pixels adjacent to the visible-light pixel PDc and the infrared-light pixel PDw sharing the pixel transistor 33.

Specifically, the penetrating pixel separation region of Example 4 extends between the pixel transistor 33 shared by the visible-light pixel PDc and the infrared-light pixel PDw, and another pixel transistor 33 shared by another visible-light pixel PDc and another infrared-light pixel PDw adjacent to the visible-light pixel PDc and the infrared-light pixel PDw.

As a result, the pixel array unit according to Example 4 can suppress the occurrence of color mixing by suppressing the entry of leakage light from the pixel transistor 33 to the adjacent pixel transistor 33.

Furthermore, as illustrated in FIG. 8B, the shallow trench part 231 of Example 4 is provided from the light receiving surface of the semiconductor layer 20 to a depth not in contact with the pixel transistor 33. As a result, in the pixel array unit according to Example 4, an etching stopper becomes unnecessary in the step of forming the shallow trench part 231. Thus, the manufacturing process can be facilitated.

### Example 5

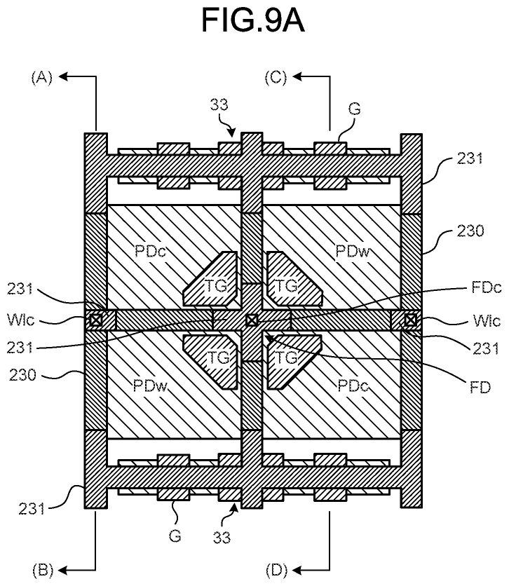

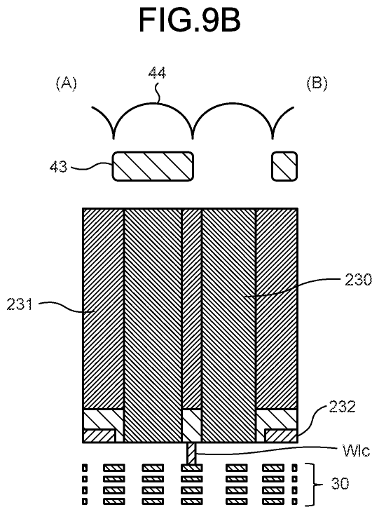

FIG. 9A is a plan view of a pixel array unit according to Example 5 of the present disclosure. FIG. 9B is a cross-sectional view taken along line (A)-(B) of the pixel array unit according to Example 5 of the present disclosure. Note that a cross section taken along line (C)-(D) of the pixel array unit illustrated in FIG. 9A has the same configuration as the cross section illustrated in FIG. 8B.

As illustrated in FIGS. 9A and 9B, the pixel array unit according to Example 5 is different from the pixel array unit according to Example 4 in the configuration in which the shallow trench part 231 extends between the visible-light pixel PDc and the infrared-light pixel PDw and adjacent pixels that share the pixel transistor 33. Other components are similar to those of the pixel array unit according to Example 4.

Specifically, the shallow trench part 231 provided in the region corresponding to the pixel transistor 33 of Example 5 extends between the pixel transistor 33 shared by the visible-light pixel PDc and the infrared-light pixel PDw and a pixel transistor 33 shared by another visible-light pixel PDc and another infrared-light pixel PDw adjacent to the visible-light pixel PDc and the infrared-light pixel PDw.

As a result, in the pixel array unit according to Example 5, since the region of the deep trench part 230 is narrower than that in the pixel array unit according to the fourth example, it is possible to suppress a dark current caused by surface roughness of the semiconductor layer 20 due to the formation of the deep trench part 230.

### Example 6

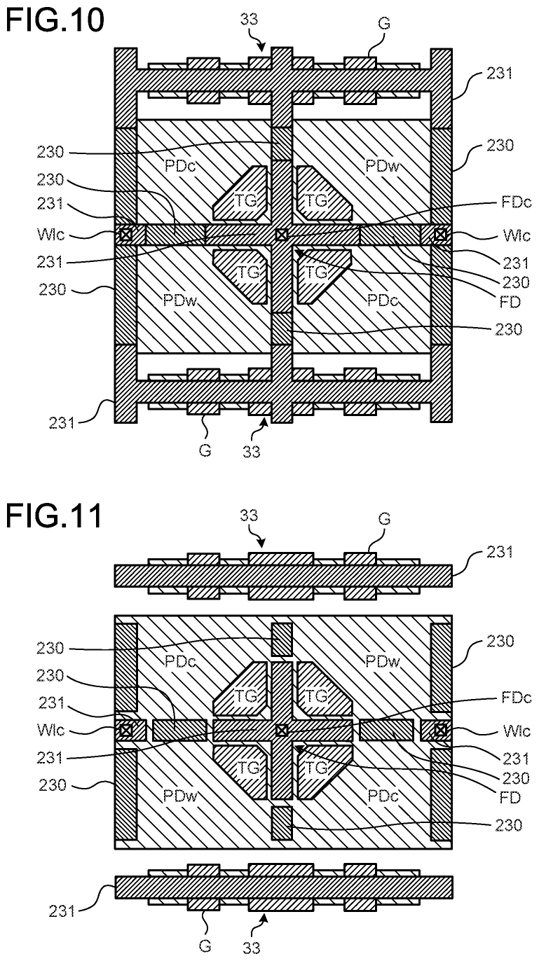

FIG. 10 is a plan view of a pixel array unit according to Example 6 of the present disclosure. As illustrated in FIG. 10, in the pixel array unit according to Example 6, a length in a longitudinal direction of the deep trench part 230 provided between the visible-light pixel PDc and the infrared-light pixel PDw sharing the floating diffusion region FD is shorter than a length in the longitudinal direction of the deep trench part 230 according to Example 5. Other components are similar to those of the pixel array unit according to Example 5.

As a result, in the pixel array unit of Example 6, since the region of the deep trench part 230 is reduced, it is possible to suppress the dark current caused by surface roughness of the semiconductor layer 20 due to the formation of the deep trench part 230.

Note that, in the pixel array unit of Example 6, the length of the deep trench part 230 in the longitudinal direction is short as described above, but since the deep trench part 230 and the shallow trench part 231 are in contact and continuous in plan view, it is possible to suppress the entry of leakage light to the adjacent pixel.

### Example 7

FIG. 11 is a plan view of a pixel array unit according to Example 7 of the present disclosure. As illustrated in FIG. 11, the pixel array unit according to Example 7 is different from the pixel array unit according to Example 6 in that the deep trench part 230 and the shallow trench part 231 are not in contact with each other in plan view. Other components are similar to those of the pixel array unit according to Example 6.

As a result, in the pixel array unit of Example 7, even when a slight misalignment occurs in a process of forming the deep trench part 230 and the shallow trench part 231, the misalignment can be allowed by a space between the deep trench part 230 and the shallow trench part 231.

### Example 8

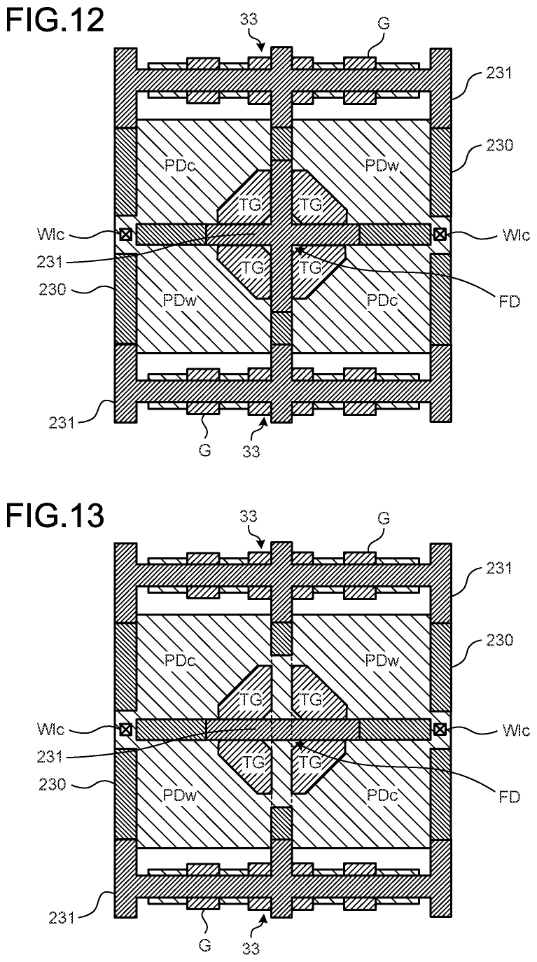

FIG. 12 is a plan view of a pixel array unit according to Example 8 of the present disclosure. As illustrated in FIG. 12, the pixel array unit according to Example 8 is different from the pixel array unit according to Example 6 in that the shallow trench part 231 is not provided in the region corresponding to the well contact Wlc in the inter-pixel region. Other components are similar to those of the pixel array unit according to Example 6.

### Example 9

FIG. 13 is a plan view of a pixel array unit according to Example 9 of the present disclosure. As illustrated in FIG. 13, a pixel array according to Example 9 is different from a pixel array according to Example 8 in that the shallow trench part 231 in the column direction is not provided in a region intersecting the region corresponding to the floating diffusion region FD among the shallow trench parts 231. Other components are similar to those of the pixel array unit according to Example 8.

### Example 10

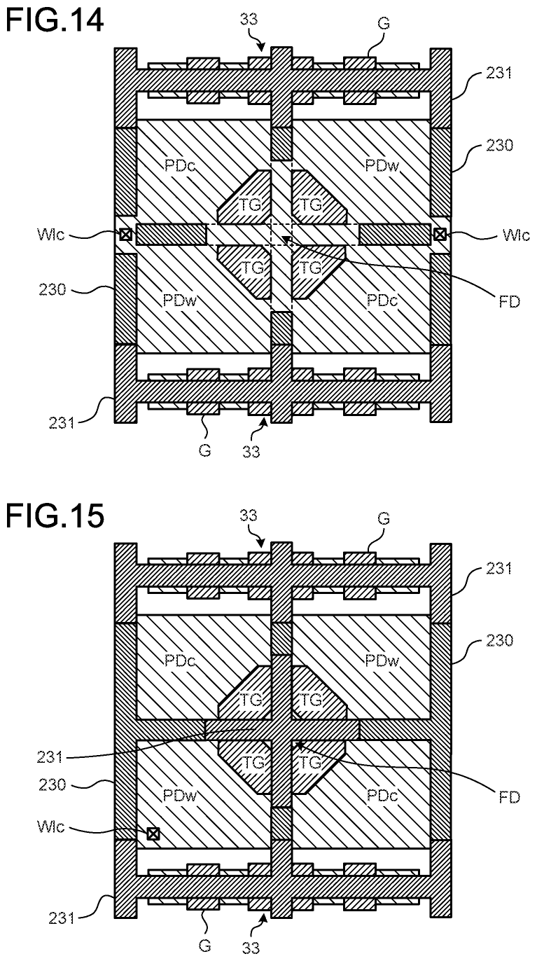

FIG. 14 is a plan view of a pixel array unit according to Example 10 of the present disclosure. As illustrated in FIG. 14, the pixel array unit according to Example 10 is different from the pixel array according to Example 8 in that the shallow trench part 231 is not provided in the region where the shallow trench part 231 intersects the region corresponding to the floating diffusion region FD. Other components are similar to those of the pixel array unit according to Example 8.

In the pixel array unit according to Examples 8 to 10, since the region of the shallow trench part 231 becomes small, it is possible to suppress the dark current caused by the surface roughness of the semiconductor layer 20 due to the formation of the shallow trench part 231.

### Example 11

FIG. 15 is a plan view of a pixel array unit according to Example 11 of the present disclosure. As illustrated in FIG. 15, the pixel array unit according to Example 11 is different from the pixel array unit according to Example 8 in that the well contact Wlc is provided in one infrared-light pixel PDw among the four pixels.

Furthermore, in the pixel array according to Example 11, the deep trench part 230 is provided in a region other than the floating diffusion region FD and the region corresponding to the pixel transistor 33 in the inter-pixel region.

In the pixel array unit according to Example 11, the areas of the visible-light pixels PDc and the infrared-light pixel PDw not provided with the well contact Wlc can be widened, and thus the saturation electron amount, the photoelectric conversion efficiency, the sensitivity, and the S/N ratio can be improved.

### Example 12

FIG. 16A is a plan view of a pixel array unit according to Example 12 of the present disclosure. FIG. 16B is a cross-sectional view taken along line (A)-(B) of the pixel array unit according to Example 12 of the present disclosure. As illustrated in FIG. 16A, the pixel array unit according to Example 12 includes the floating diffusion region FD that is shared between the visible-light pixel PDc and the infrared-light pixel PDw adjacent in the column direction. Furthermore, the pixel array unit according to Example 12 includes the well contact Wlc between the visible-light pixel PDc and the infrared-light pixel PDw adjacent in the column direction.

Then, in the pixel array unit according to Example 12, as illustrated in FIGS. 16A and 16B, the shallow trench part 231 is provided in the region corresponding to the floating diffusion region DF, the well contact Wlc, and the pixel transistor 33 in the inter-pixel region.

Furthermore, in the pixel array unit according to Example 12, the deep trench part 230 is provided between the pixels sharing the floating diffusion region FD and the pixels sharing another floating diffusion region FD. The deep trench part 230 is also provided between the pixels sharing the floating diffusion region FD.

As described above, in the pixel array unit according to Example 12, one floating diffusion region FD and one well contact Wlc are shared by two pixels. As a result, since the pixel array unit according to Example 12 can be miniaturized and the pixel area can be increased, the saturation electron amount, the photoelectric conversion efficiency, the sensitivity, and the S/N ratio can be improved. Furthermore, in the pixel array unit according to Example 12, color mixing can be suppressed by shielding between the visible-light pixel PDc and the infrared-light pixel PDw by the deep trench part 230.

### Example 13

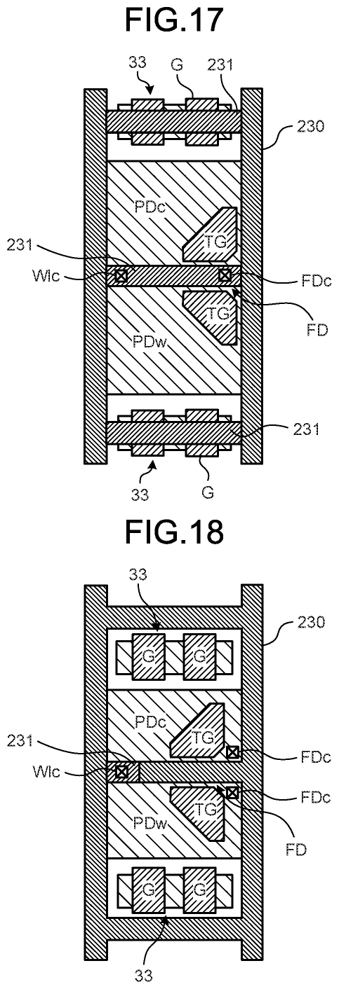

FIG. 17 is a plan view of a pixel array unit according to Example 13 of the present disclosure. As illustrated in FIG. 17, the pixel array unit according to Example 13 is different from the pixel array unit according to Example 12 in that the visible-light pixel PDc and the infrared-light pixel PDw sharing the floating diffusion region FD are separated by the shallow trench part 231. Other components are similar to those of the pixel array unit according to Example 12.

The pixel array unit according to Example 13 can be miniaturized while suppressing color mixing, and can also widen the areas of the visible-light pixel PDc and the infrared-light pixel PDw. Thus, the saturation electron amount, the photoelectric conversion efficiency, the sensitivity, and the S/N ratio can be improved.

In addition, in the pixel array according to Example 13, since all shapes of the deep trench part 230 and the shallow trench part 231 in plan view are linear, the pixel separation region can be formed using a mask of a simple pattern, and thus the manufacturing process is facilitated.

### Example 14

FIG. 18 is a plan view of a pixel array unit according to Example 14 of the present disclosure. As illustrated in FIG. 18, in the pixel array unit according to Example 14, the shallow trench part 231 is provided in the region corresponding to the well contact Wlc shared by the visible-light pixel PDc and the infrared-light pixel PDw.

Still more, in the pixel array unit according to Example 14, the deep trench part 230 is provided in a region other than the region corresponding to the well contact Wlc in the inter-pixel region. Note that the floating diffusion region and the pixel transistor 33 are provided adjacent to each other in each of the visible-light pixel PDc and the infrared-light pixel PDw.

### Example 15

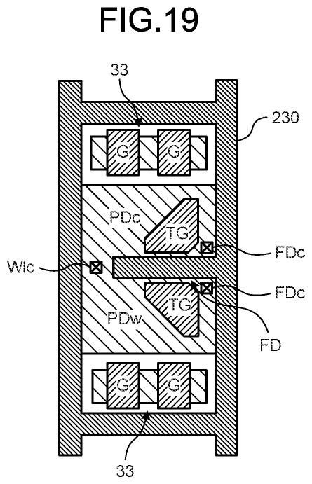

FIG. 19 is a plan view of a pixel array unit according to Example 15 of the present disclosure. The pixel array unit according to Example 15 is different from the pixel array unit according to Example 14 in that the shallow trench part 231 is not provided in the region corresponding to the well contact Wlc shared by the visible-light pixel PDc and the infrared-light pixel PDw. Other components are similar to those of the pixel array unit according to Example 14.

In the pixel array unit according to Examples 14 and 15, all the regions except for the region corresponding to the well contact Wlc shared in the inter-pixel region of the adjacent visible-light pixel PDc and infrared-light pixel PDw are separated by the deep trench part 230 to achieve the penetrating pixel separation region. As a result, the pixel array units according to Examples 14 and 15 can more reliably suppress color mixing.

### Example 16

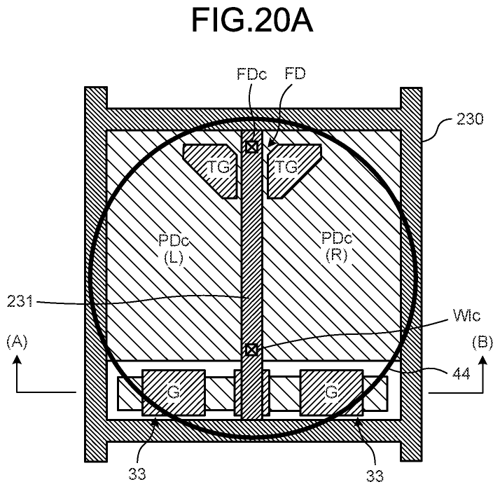

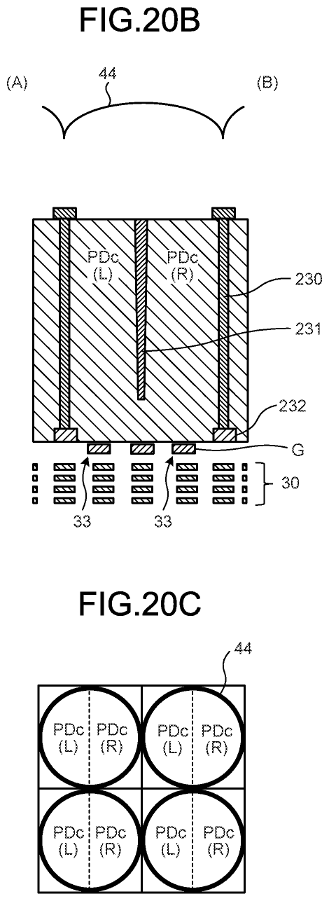

FIG. 20A is a plan view of a pixel array unit according to Example 16 of the present disclosure. FIG. 20B is a cross-sectional view taken along line (A)-(B) of the pixel array unit according to Example 16 of the present disclosure. FIG. 20C is a plan view of the pixel array unit according to Example 16 of the present disclosure.

As illustrated in FIGS. 20A and 20B, in the pixel array unit according to Example 16, the shallow trench part 231 is provided at a position where the light receiving pixels having a square planar shape are separated into two visible-light pixels PDc (L) and PDc (R) having an equal area and a rectangular planar shape. Note that a pair of light receiving pixels having the rectangular planar shape may be infrared-light pixels PDw (L) and PDw (R).

The floating diffusion region DF and the well contact Wlc to be shared are provided between the pair of visible-light pixels PDc (L) and PDc (R). Furthermore, the pixel transistor 33 to be shared is provided adjacent to the pair of visible-light pixels PDc (L) and PDc (R).

Furthermore, in the pixel array unit according to Example 16, the deep trench part 230 is provided between the pair of visible-light pixels PDc (L) and PDc (R) and an adjacent pixel. Furthermore, the pixel array unit according to Example 16 includes an on-chip lens 44 on the light receiving surfaces of the pair of visible-light pixels PDc (L) and PDc (R). The on-chip lens 44 has a circular planar shape and surrounds the pair of visible-light pixels PDc (L) and PDc (R). As illustrated in FIG. 20C, a plurality of the pair of visible-light pixels PDc (L) and PDc (R) is arranged in a matrix.

The visible-light pixel PDc (L) captures, for example, each pixel of an image visually recognized by the left eye of a person. The visible-light pixel PDc (R) captures, for example, each pixel of an image visually recognized by the right eye of a person. As a result, the pixel array unit according to Example 16 can capture a three-dimensional (3D) image using a left and right parallax.

As described above, in the pixel array unit according to Example 16, the shallow trench part 231 is provided between the pair of visible-light pixels PDc (L) and PDc (R). As a result, in the pixel array unit according to Example 16, the optical path lengths of the pair of visible-light pixels PDc (L) and PDc (R) can be increased, and thus the sensitivity can be improved.

Furthermore, since the pixel array unit according to Example 16 can share the floating diffusion region DF and the well contact Wlc by the pair of visible-light pixels PDc (L) and PDc (R), miniaturization is possible.

Furthermore, in the pixel array unit according to Example 16, since the deep trench part 230 is provided around the pair of visible-light pixels PDc (L) and PDc (R), color mixing in the three-dimensional (3D) image to be captured can be suppressed.

### Example 17

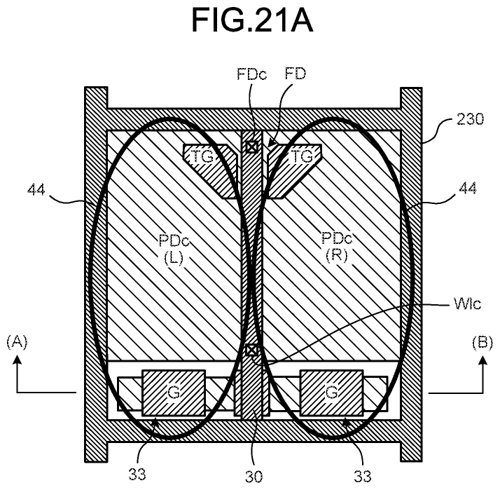

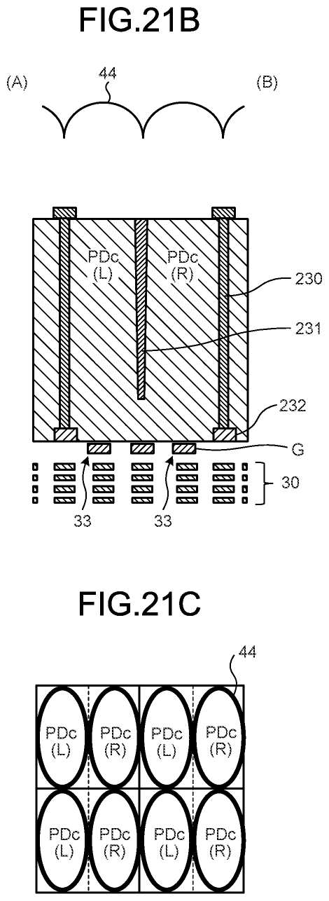

FIG. 21A is a plan view of a pixel array unit according to Example 17 of the present disclosure. FIG. 21B is a cross-sectional view taken along line (A)-(B) of the pixel array unit according to Example 17 of the present disclosure. FIG. 21C is a plan view of the pixel array unit according to Example 17 of the present disclosure.

As illustrated in FIGS. 21A and 21B, the pixel array unit according to Example 17 includes the on-chip lens 44 on the light receiving surface of each of the pair of visible-light pixels PDc (L) and PDc (R). The on-chip lens 44 has an elliptical planar shape and surrounds each of the visible-light pixels PDc (L) and PDc (R). Other components are similar to those of the pixel array unit according to Example 16. As illustrated in FIG. 21C, a plurality of visible-light pixels PDc (L) and PDc (R) is arranged in a matrix.

Also in the pixel array unit according to Example 17, the shallow trench part 231 is provided between the pair of visible-light pixels PDc (L) and PDc (R). As a result, in the pixel array unit according to Example 17, optical path length of the pair of visible-light pixels PDc (L) and PDc (R) can be increased, and thus the sensitivity can be improved.

Furthermore, since the pixel array unit according to Example 17 can share the floating diffusion region DF and the well contact Wlc by the pair of visible-light pixels PDc (L) and PDc (R), miniaturization is possible.

Furthermore, in the pixel array unit according to Example 17, since the deep trench part 230 is provided around the pair of visible-light pixels PDc (L) and PDc (R), color mixing in the 3D image to be captured can be suppressed.

### Example 18

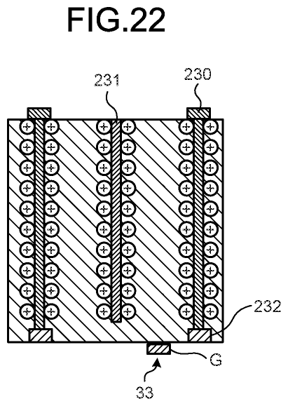

FIG. 22 is an explanatory diagram of a pixel array unit according to Example 18 of the present disclosure. As illustrated in FIG. 22, in the pixel array unit according to Example 18, conductors are embedded inside the deep trench part 230 and the shallow trench part 231, and holes are collected on surfaces of the deep trench part 230 and the shallow trench part 231 by applying a negative voltage from outside.

As a result, the pixel array unit according to Example 18 can suppress a defective pixel called a white spot and the dark current by recombining electrons and holes generated by an interface state and defect on the interface between the deep trench part 230 and the shallow trench part 231 and the semiconductor layer 20.

### Modification 1

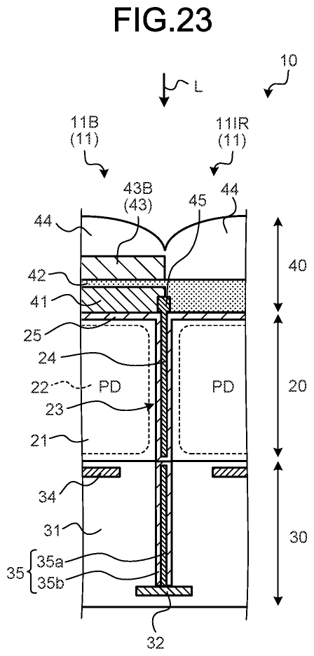

FIG. 23 is a cross-sectional view schematically illustrating a structure of the pixel array unit 10 according to Modification 1 of the embodiment of the present disclosure. As illustrated in FIG. 23, in the pixel array unit 10 of Modification 1, the light shielding wall 24 of the pixel separation region 23 is provided so as to penetrate the semiconductor layer 20.

Furthermore, Modification 1 provides a light shielding part 35 penetrating from a tip end of the light shielding wall 24 to the wiring 32 in the wiring layer 30 in a light incident direction. The light shielding part 35 includes a light shielding wall 35a and a metal oxide film 35b.

The light shielding wall 35a is a wall-shaped film that is provided along the separation region 23 in plan view and shields light entering from adjacent unit pixels 11. The metal oxide film 35b is provided so as to cover the light shielding wall 35a in the light shielding part 35. The light shielding wall 35a is made of the same material as the light shielding wall 24, and the metal oxide film 35b is made of the same material as the metal oxide film 25.

As illustrated in FIG. 23, it is possible to further suppress stray light leaking from the IR pixel 11IR to the adjacent unit pixel 11 by providing the light shielding part 35 connected to the tip end of the light shielding wall 24. Therefore, Modification 1 can further suppress the occurrence of color mixing.

### Modification 2

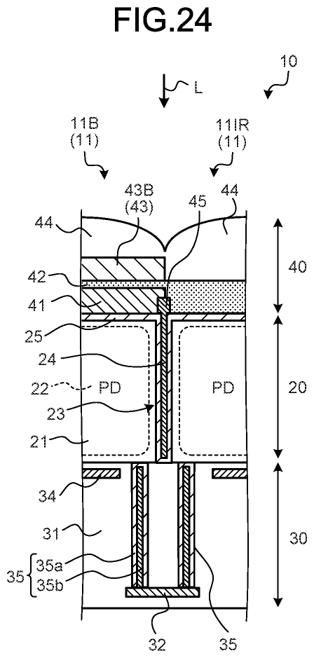

FIG. 24 is a cross-sectional view schematically illustrating a structure of the pixel array unit 10 according to Modification 2 of the embodiment of the present disclosure. As illustrated in FIG. 24, in the pixel array unit 10 of Modification 2, the light shielding wall 24 of the separation region 23 is provided so as to penetrate the semiconductor layer 20.

Furthermore, Modification 2 provides a pair of light shielding parts 35 penetrating from a position adjacent to the tip end of the light shielding wall 24 to the wiring 32 of the wiring layer 30 in the light incident direction. In other words, the pixel array unit 10 according to Modification 2 is configured such that the tip end of the light shielding wall 24 is surrounded by the pair of light shielding parts 35.

This also makes it possible to further suppress the stray light leaking and mixing from the IR pixel 11IR to the adjacent unit pixel 11. Therefore, Modification 2 can further suppress the occurrence of color mixing. Note that, in the example in FIG. 24, the light shielding wall 24 may not necessarily be formed so as to penetrate the semiconductor layer 20.

### Modification 3

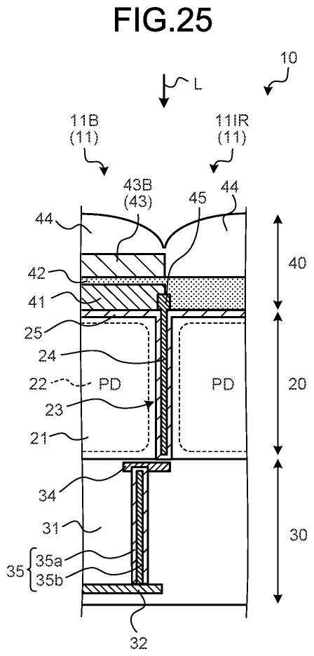

FIG. 25 is a cross-sectional view schematically illustrating a structure of the pixel array unit 10 according to Modification 3 of the embodiment of the present disclosure. As illustrated in FIG. 25, in the pixel array unit 10 of Modification 3, the light shielding wall 24 of the separation region 23 is provided so as to penetrate the semiconductor layer 20 and also reach the metal layer 34 of the wiring layer 30.

Furthermore, Modification 3 provides a pair of the light shielding parts 35 penetrating from a position different from the light shielding wall 24 in the metal layer 34 to the wiring 32 of the wiring layer 30 in the light incident direction. In other words, in Modification 3, the light shielding wall 24, the metal layer 34, and the light shielding parts 35 are configured as an integrated portion having a light shielding function.

This also makes it possible to further suppress the stray light leaking and mixing from the IR pixel 11IR to the adjacent unit pixel 11. Therefore, Modification 3 can further suppress the occurrence of color mixing.

<Details of IR Cut Filter>

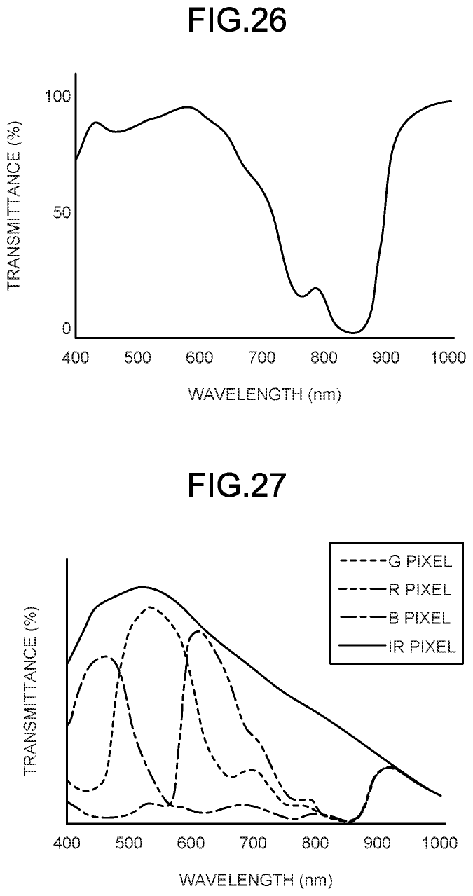

Next, details of the IR cut filter 41 provided in the visible-light pixel will be described with reference to FIGS. 26 to 32 and FIG. 4 described above. FIG. 26 is a diagram illustrating an example of spectral characteristic of the IR cut filter 41 according to the embodiment of the present disclosure.

As illustrated in FIG. 26, the IR cut filter 41 has the spectral characteristic in which transmittance is 30(%) or less in a wavelength region of 700 (nm) or more, and particularly has an absorption maximum wavelength in a wavelength region near 850 (nm).

Then, as illustrated in FIG. 4, in the pixel array unit 10 according to the embodiment, the IR cut filter 41 is arranged on the surface on the light incident side of the semiconductor layer 20 in the visible-light pixel, and is not arranged on the surface on the light incident side of the semiconductor layer 20 in the IR pixel 11IR.

Furthermore, in the pixel array unit 10 according to the embodiment, the color filter 43R that transmits red light is arranged in the R pixel 11R, and the color filter 43G that transmits green light is arranged in the G pixel 11G. Furthermore, in the pixel array unit 10 according to the embodiment, the color filter 43B that transmits blue light is arranged in the B pixel 11B.

With these filters, the spectral characteristic of the light incident on the photodiodes PD of the R pixel 11R, the G pixel 11G, the B pixel 11B, and the IR pixel 11IR will be as illustrated in a graph in FIG. 27. FIG. 27 is a graph illustrating an example of the spectral characteristic of each unit pixel according to the embodiment of the present disclosure.

As illustrated in FIG. 27, in the pixel array unit 10 according to the embodiment, the spectral characteristics of the R pixel 11R, the G pixel 11G, and the B pixel 11B have low transmittance in the infrared light region with wavelengths of about 750 (nm) to 850 (nm).

In other words, in the embodiment, an influence of the entry of the infrared light in the visible-light pixel can be reduced by providing the IR cut filter 41 in the visible-light pixel. Thus, noise of a signal output from the photodiode PD of the visible-light pixel can be reduced.

Furthermore, in the pixel array unit 10 according to the embodiment, since the IR cut filter 41 is not provided in the IR pixel 11IR, as illustrated in FIG. 27, the spectral characteristic of the IR pixel 11IR maintains high transmittance in the infrared region.

In other words, in the embodiment, since more infrared light can enter the IR pixel 11IR, an intensity of the signal output from the IR pixel 11IR can be increased.

As described above, in the pixel array unit 10 according to the embodiment, the quality of the signal output from the pixel array unit 10 can be improved by providing the IR cut filter 41 only in the visible-light pixel.

Furthermore, in the embodiment, as illustrated in FIG. 4, since the IR cut filter 41 is not provided in the IR pixel 11IR, the planarization film 42 is in direct contact with the metal oxide film 25 of the semiconductor layer 20 in the IR pixel 11IR.

As described above, reflection and diffraction on a surface of the metal oxide film 25 can be suppressed by bringing the planarization film 42 having a refractive index close to that of the metal oxide film 25 into direct contact with the metal oxide film 25.

Therefore, according to the embodiment, the amount of light L that passes through the surface of the metal oxide film 25 and enters the photodiode PD of the IR pixel 11IR can be increased. Thus, the intensity of the signal output from the IR pixel 11IR can be further increased.

The IR cut filter 41 is formed of an organic material to which a near infrared absorbing dye is added as an organic coloring material. Examples of the near-infrared absorbing dye include a pyrrolopyrrole dye, a copper compound, a cyanine dye, a phthalocyanine compound, an imonium compound, a thiol complex compound, and a transition metal oxide compound.

In addition, as the near-infrared absorbing dye used for the IR cut filter 41, for example, a squarylium dye, a naphthalocyanine dye, a quaterylene dye, a dithiol metal complex dye, a croconium compound, and the like are also used.

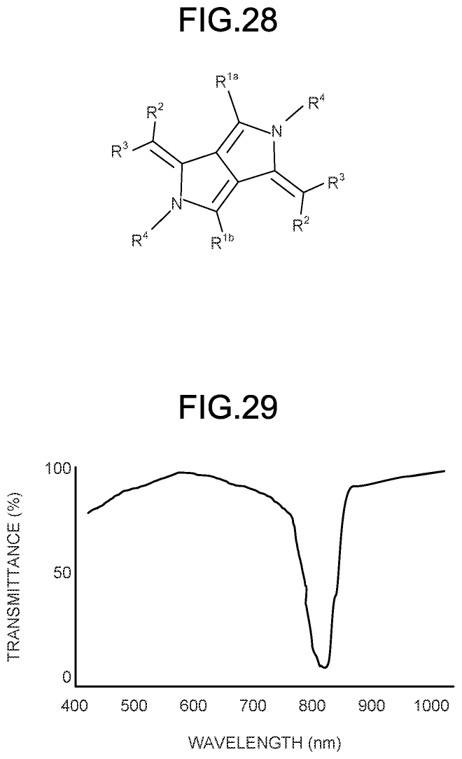

For the IR pixel 11IR according to the embodiment, the coloring material of the IR cut filter 41 is preferably a pyrrolopyrrole dye represented by the chemical formula in FIG. 28. FIG. 28 illustrates an example of the coloring material of the IR cut filter 41 according to the embodiment of the present disclosure.

In FIG. 28, each of R^{1a} and R^{1b} independently represents an alkyl group, an aryl group, or a heteroaryl group. Each of R² and R³ independently represents a hydrogen atom or a substituent, and at least one of R² and R³ is an electron-attracting group. The R² and R³ may be bonded to each other to form a ring.

A hydrogen atom, an alkyl group, an aryl group, a heteroaryl group, substituted boron, or a metal atom is represented by R⁴. The R⁴ may be covalently bonded or coordinate-bonded to at least one of the R^{1a}, R^{1b}, and R³.

In the example in FIG. 26 described above, the spectral characteristic of the IR cut filter 41 has the absorption maximum wavelength in the wavelength region close to 850 (nm), but the transmittance may be 30(%) or less in the wavelength region of 700 (nm) or more.

FIGS. 29 to 32 are diagrams illustrating another example of the spectral characteristic of the IR cut filter 41 according to the embodiment of the present disclosure. For example, as illustrated in FIG. 29, the spectral characteristic of the IR cut filter 41 may have the transmittance of 20(%) in the wavelength region of 800 (nm) or more.

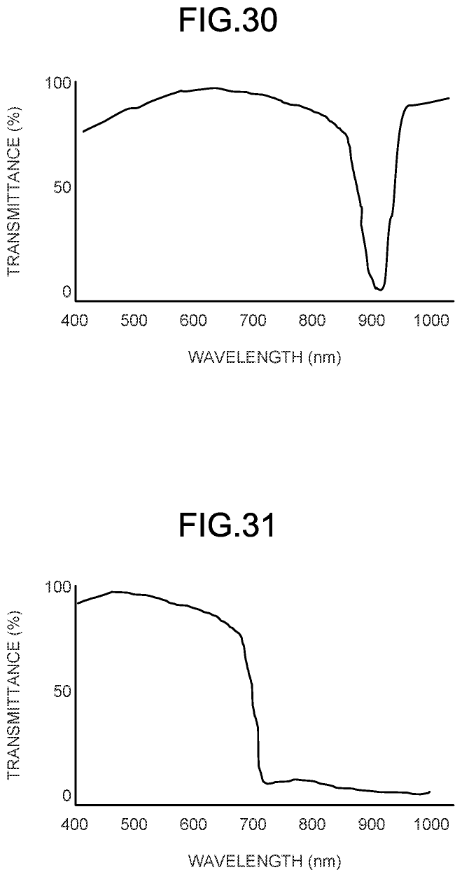

Furthermore, as illustrated in FIG. 30, the spectral characteristic of the IR cut filter 41 may have the absorption maximum wavelength in a wavelength region close to 950 (nm). Furthermore, as illustrated in FIG. 31, the spectral characteristic of the IR cut filter 41 may be such that the transmittance is 20(%) or less in the entire wavelength region of 750 (nm) or more.

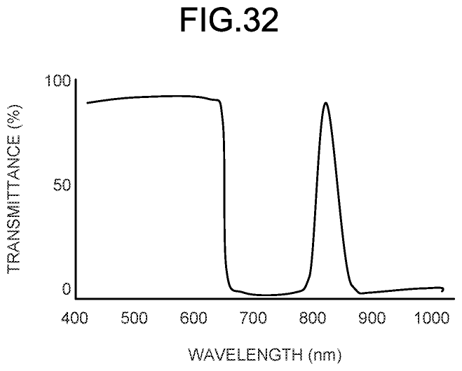

Furthermore, as illustrated in FIG. 32, the spectral characteristic of the IR cut filter 41 may transmit the infrared light having wavelengths of 800 (nm) to 900 (nm) in addition to the visible light.

As described above, by determining the absorption maximum wavelength by the coloring material added to the IR cut filter 41, the IR cut filter 41 can be an optical filter that selectively absorbs the infrared light in a predetermined wavelength region in the visible-light pixel. Furthermore, the maximum absorption wavelength of the IR cut filter 41 can be appropriately determined according to an application of the solid-state imaging element 1.

### Modification 4

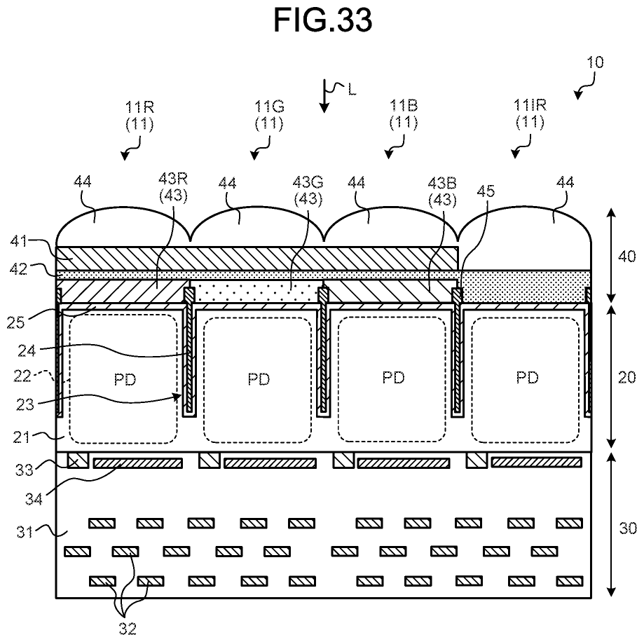

The embodiment and various modifications described so far give examples in which the IR cut filter 41 is provided on the surface of the semiconductor layer 20 on the light incident side. However, the arrangement of the IR cut filter 41 in the present disclosure is not limited thereto. FIG. 33 is a cross-sectional view schematically illustrating a structure of the pixel array unit 10 according to Modification 4 of the embodiment of the present disclosure.

As illustrated in FIG. 33, in the pixel array unit 10 of Modification 4, the IR cut filter 41 and the color filter 43 are switched in the arrangement. In other words, in Modification 4, the color filter 43 is arranged on the surface of the semiconductor layer 20 on the light incident side surface in the visible-light pixel (R pixel 11R, G pixel 11G, and B pixel 11B).

In addition, the planarization film 42 is provided to planarize the surface on which the IR cut filter 41 and the OCL 44 are formed to avoid unevenness that may occur in a rotational coating process when the IR cut filter 41 and the OCL 44 are formed.

Then, the IR cut filter 41 is arranged on the surface of the planarization film 42 on the light incident side in the visible-light pixel (R pixel 11R, G pixel 11G, and B pixel 11B).

As a result, the quality of the signal output from the pixel array unit 10 can also be improved by providing the IR cut filter 41 only in the visible-light pixel.

### Modification 5

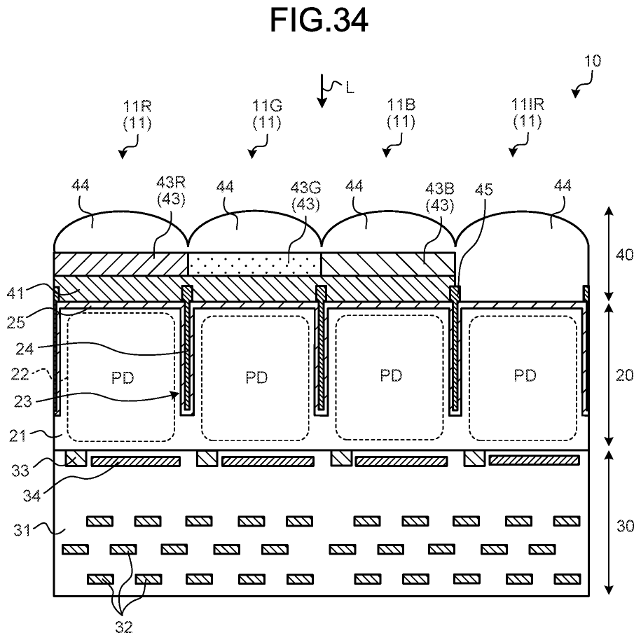

FIG. 34 is a cross-sectional view schematically illustrating a structure of the pixel array unit 10 according to Modification 5 of the embodiment of the present disclosure. As illustrated in FIG. 34, Modification 5 omits the planarization film 42 for planarizing the surface after the IR cut filter 41 is formed in the pixel array unit 10.

In other words, in Modification 5, the color filter 43 is arranged on the surface of the IR cut filter 41 on the light incident side in the visible-light pixel (R pixel 11R, G pixel 11G, and B pixel 11B).

As a result, the quality of the signal output from the pixel array unit 10 can also be improved by providing the IR cut filter 41 only in the visible-light pixel.

### Modification 6

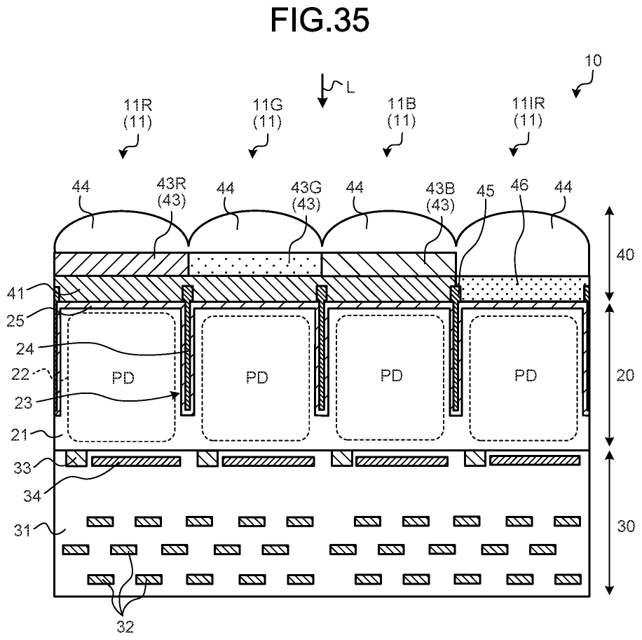

FIG. 35 is a cross-sectional view schematically illustrating a structure of the pixel array unit 10 according to Modification 6 of the embodiment of the present disclosure. As illustrated in FIG. 35, similarly to Modification 5 described above, Modification 6 omits the planarization film 42 for planarizing the surface after the IR cut filter 41 is formed in the pixel array unit 10.

Furthermore, Modification 6 provides a transparent material 46 between the metal oxide film 25 of the semiconductor layer 20 and the OCL 44 in the IR pixel 11IR. The transparent material 46 has an optical characteristic of transmitting at least the infrared light, and is formed in a photolithography process after the IR cut filter 41 is formed.

As a result, the quality of the signal output from the pixel array unit 10 can also be improved by providing the IR cut filter 41 only in the visible-light pixel.

### Modification 7

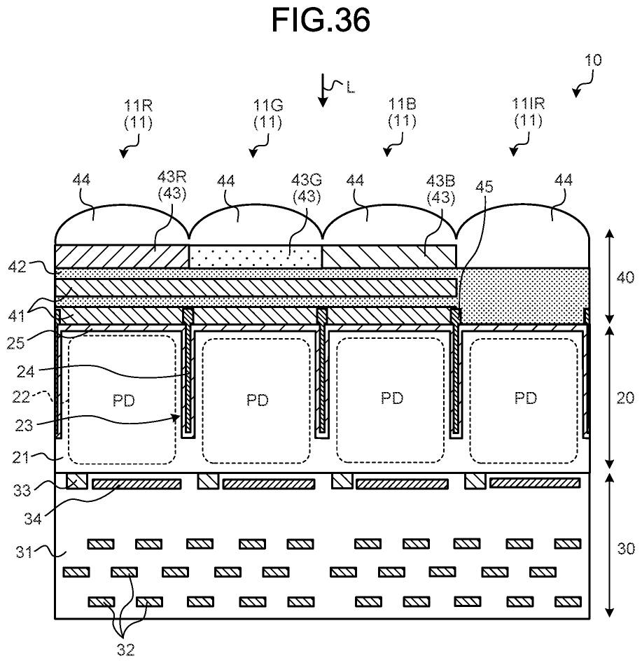

FIG. 36 is a cross-sectional view schematically illustrating a structure of the pixel array unit 10 according to Modification 7 of the embodiment of the present disclosure. As illustrated in FIG. 36, in the pixel array unit 10 of Modification 7, the IR cut filter 41 has multiple layers (two layers in the drawing).

The multiple layers of the IR cut filter 41 can be formed, for example, by repeating a process of forming a single layer of the IR cut filter 41 and a process of planarizing the surface with the planarization film 42.

Here, when one thick layer of the IR cut filter 41 is planarized by the planarization film 42, unevenness may occur in the planarization film 42 when the planarization film 42 is formed.

However, in Modification 7, since the IR cut filter 41 having a small film thickness is planarized by the planarization film 42, occurrence of unevenness in the planarization film 42 can be suppressed. Furthermore, in Modification 7, a total film thickness of the IR cut filter 41 can be increased by providing the multiple layers of the IR cut filter 41.

Therefore, according to Modification 7, the pixel array unit 10 can be formed with high accuracy, and the quality of the signal output from the pixel array unit 10 can be further improved.

### Modification 8

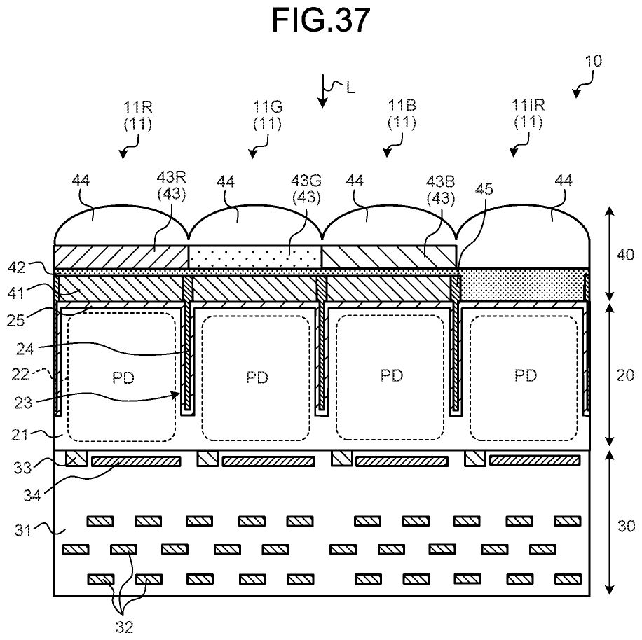

FIG. 37 is a cross-sectional view schematically illustrating a structure of the pixel array unit 10 according to Modification 8 of the embodiment of the present disclosure. As illustrated in FIG. 37, in the pixel array unit 10 of Modification 8, the light shielding wall 45 is provided so as to penetrate the IR cut filter 41.

As a result, it is possible to further suppress the entry of light transmitted through the IR cut filter 41 and the planarization film 42 of the adjacent unit pixels 11, and thus, it is possible to further suppress the occurrence of color mixing.

### Modification 9

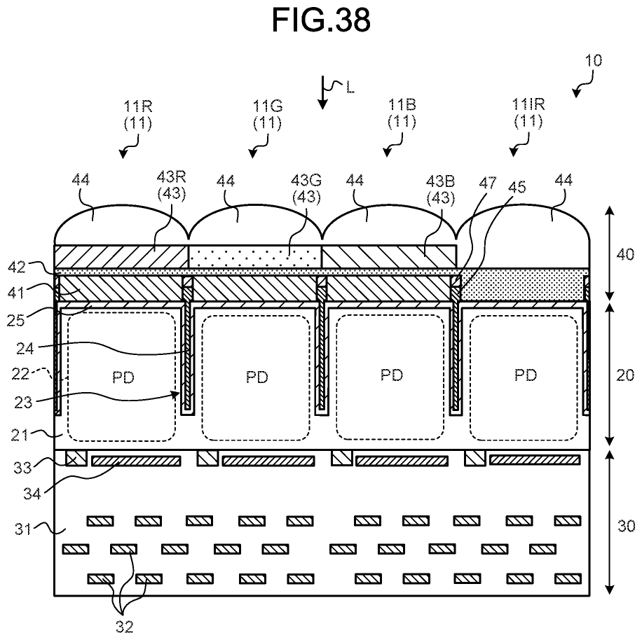

FIG. 38 is a cross-sectional view schematically illustrating a structure of the pixel array unit 10 according to Modification 9 of the embodiment of the present disclosure. As illustrated in FIG. 38, in the pixel array unit 10 of Modification 9, an optical wall 47 is provided on the light incident side of the light shielding wall 45. Then, in Modification 9, the light shielding wall 45 and the optical wall 47 are integrally provided so as to penetrate the IR cut filter 41.

The optical wall 47 is made of a material having a low refractive index (e.g., n≤1.6) such as silicon oxide or an organic material having a low refractive index.

This also makes it possible to further suppress the entry of light transmitted through the IR cut filter 41 and the planarization film 42 of the adjacent unit pixels 11, and thus, it is possible to further suppress the occurrence of color mixing.

<Peripheral Structure of Solid-State Imaging Element>

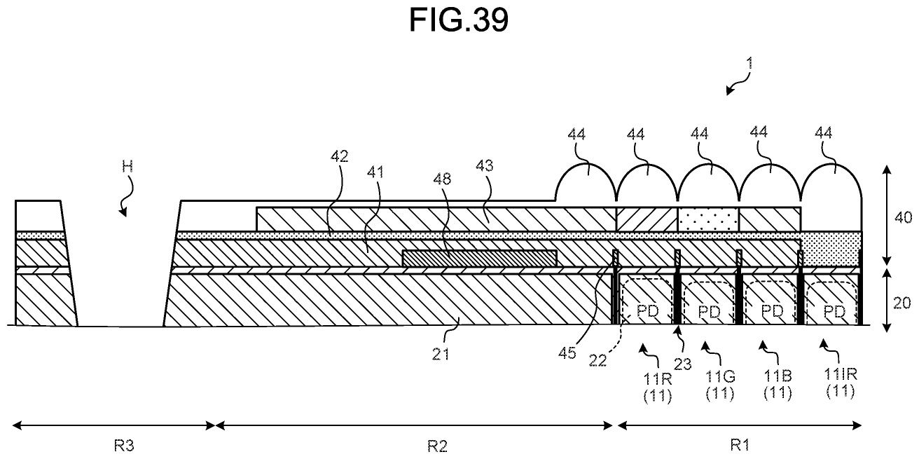

FIG. 39 is a cross-sectional view schematically illustrating a peripheral structure of the solid-state imaging element 1 according to the embodiment of the present disclosure. FIG. 39 mainly illustrates a cross-sectional structure of a periphery of the solid-state imaging element 1. As illustrated in FIG. 39, the solid-state imaging element 1 includes a pixel region R1, a peripheral region R2, and a pad region R3.

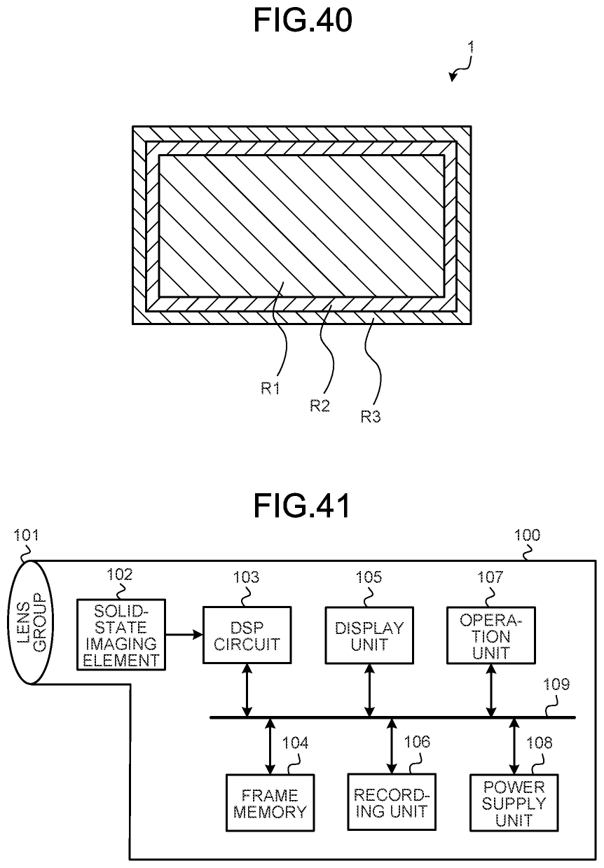

The pixel region R1 is a region where the unit pixel 11 is provided. In the pixel region R1, a plurality of the unit pixels 11 is arranged in a two-dimensional lattice pattern. Furthermore, as illustrated in FIG. 40, the peripheral region R2 is a region provided so as to surround four sides of the pixel region R1. FIG. 40 is a diagram illustrating a planar configuration of the solid-state imaging element 1 according to the embodiment of the present disclosure.

Furthermore, as illustrated in FIG. 39, a light shielding layer 48 is provided in the peripheral region R2. The light shielding layer 48 is a film that shields light obliquely entering the pixel region R1 from the peripheral region R2.

It is possible to suppress the entry of the light L from the peripheral region R2 to the unit pixels 11 in the pixel region R1 by providing the light shielding layer 48. Thus, it is possible to suppress the occurrence of color mixing. The light shielding layer 48 is made of, for example, aluminum, tungsten, or the like.

As illustrated in FIG. 40, the pad region R3 is a region provided around the peripheral region R2. As illustrated in FIG. 39, the pad region R3 has a contact hole H. A bonding pad (not illustrated) is provided at the bottom of the contact hole H.

Then, the pixel array unit 10 and each part of the solid-state imaging element 1 are electrically connected by bonding a bonding wire or the like to the bonding pad via the contact hole H.

Here, in the embodiment, as illustrated in FIG. 39, the IR cut filter 41 is preferably formed not only in the pixel region R1 but also in the peripheral region R2 and the pad region R3.

As a result, it is possible to further suppress the entry of the infrared light from the peripheral region R2 and the pad region R3 to the unit pixels 11 in the pixel region R1. Therefore, according to the embodiment, the occurrence of color mixing can be further suppressed.

Furthermore, in the embodiment, the IR cut filter 41 is also formed in the peripheral region R2 and the pad region R3, so that the occurrence of unevenness in the planarization film 42 in the peripheral region R2 and the pad region R3 can be suppressed when the planarization film 42 is formed. Therefore, according to the embodiment, the solid-state imaging element 1 can be accurately formed.

The embodiment and various modifications described above give examples in which the visible-light pixels (R pixel 11R, G pixel 11G, and B pixel 11B) and the IR pixels 11IR are arranged side by side in the pixel array unit 10. However, light receiving pixels having other functions may be added to the pixel array unit 10.

For example, a light receiving pixel for phase difference detection (hereinafter also referred to as a phase difference pixel) may be added to the pixel array unit 10 according to the embodiment, and the metal layer 34 containing tungsten as a main component may be provided in the phase difference pixel.

As a result, the color mixing caused by the IR pixel 11IR in the phase difference pixel can be suppressed. Thus, it is possible to improve autofocus performance of the solid-state imaging element 1.

Furthermore, a light receiving pixel for distance measurement using the time-of-flight (ToF) principle (hereinafter also referred to as a distance measuring pixel) may be added to the pixel array unit 10 according to the embodiment, and the metal layer 34 containing tungsten as a main component may be provided in the distance measuring pixel.

As a result, color mixing caused by the IR pixel 11IR in the distance measuring pixel can be suppressed. Thus, it is possible to improve distance measuring performance of the solid-state imaging element 1.

<Effects>

The solid-state imaging element 1 according to the present disclosure includes the semiconductor layer 20, the floating diffusion region FD, the penetrating pixel separation region (deep trench part 230, STI 232), and the non-penetrating pixel separation region (shallow trench part 231). In the semiconductor layer 20, the visible-light pixel PDc that receives visible light and performs photoelectric conversion, and the infrared-light pixel PDw that receives the infrared light and performs photoelectric conversion are two-dimensionally arranged. The floating diffusion region FD is provided in the semiconductor layer 20 and is shared by the visible-light pixel PDc and infrared-light pixel PDw adjacent to each other. The penetrating pixel separation region (deep trench part 230, STI 232) is provided in the region excluding the region corresponding to the floating diffusion region FD in the inter-pixel region of the visible-light pixel PDc and the infrared-light pixel PDw, and penetrates the semiconductor layer 20 in the depth direction. The non-penetrating pixel separation region (shallow trench part 231) is provided in the region corresponding to the floating diffusion region FD in the inter-pixel region, and reaches the midway part in the depth direction from the light receiving surface of the semiconductor layer 20.

As a result, the floating diffusion region FD is shared by the visible-light pixel PDc and the infrared-light pixel PDw, and thus the solid-state imaging element 1 can be miniaturized. Furthermore, in the solid-state imaging element 1, the visible-light pixel PDc and the infrared-light pixel PDw are separated by the penetrating pixel separation region, and thus the color mixing can be suppressed.

The non-penetrating pixel separation region (shallow trench part 231) reaches the floating diffusion region FD from the light receiving surface of the semiconductor layer 20. As a result, the solid-state imaging element 1 can suppress the color mixing due to leakage light from a part of the floating diffusion region FD.

The floating diffusion region FD is shared by four pixels adjacent in the matrix direction. As a result, the solid-state imaging element 1 can be miniaturized as compared with cases where the floating diffusion region FD is provided in each of the four pixels.

The floating diffusion region FD is shared by two adjacent pixels. As a result, the solid-state imaging element 1 can be miniaturized as compared with cases where the floating diffusion region FD is provided in each of the two pixels.

The solid-state imaging element 1 according to the present disclosure includes the semiconductor layer 20, the pixel transistor 33, the penetrating pixel separation region (deep trench part 230, STI 232), and the non-penetrating pixel separation region (shallow trench part 231). In the semiconductor layer 20, the visible-light pixel PDc that receives visible light and performs photoelectric conversion, and the infrared-light pixel PDw that receives the infrared light and performs photoelectric conversion are two-dimensionally arranged. The pixel transistor 33 is provided in the semiconductor layer 20 and is shared by the visible-light pixel PDc and the infrared-light pixel PDw adjacent to each other. The penetrating pixel separation region (deep trench part 230, STI 232) is provided in the region excluding the region corresponding to the pixel transistor 33 in the inter-pixel region of the visible-light pixel PDc and the infrared-light pixel PDw, and penetrates the semiconductor layer 20 in the depth direction. The non-penetrating pixel separation region (shallow trench part 231) is provided in the region corresponding to the pixel transistor 33 in the inter-pixel region, and reaches the middle in the depth direction from the light receiving surface of the semiconductor layer 20.

As a result, in the solid-state imaging element 1, the pixel transistor 33 is shared by the visible-light pixel PDc and the infrared-light pixel PDw, and thus miniaturization is possible. Furthermore, in the solid-state imaging element 1, the visible-light pixel PDc and the infrared-light pixel PDw are separated by the penetrating pixel separation region, and thus the color mixing can be suppressed.

The penetrating pixel separation region (deep trench part 230, STI 232) extends between the pixel transistor 33 shared by the visible-light pixel PDc and the infrared-light pixel PDw and an adjacent pixel transistor 33 shared by an adjacent visible-light pixel PDc and an adjacent infrared-light pixel PDw with respect to the visible-light pixel PDc and the infrared-light pixel PDw. As a result, the solid-state imaging element 1 can suppress the occurrence of color mixing by suppressing intrusion of leakage light from the pixel transistor 33 to the adjacent pixel transistor 33.

The non-penetrating pixel separation region (shallow trench part 231) extends between the pixel transistor 33 shared by the visible-light pixel PDc and the infrared-light pixel PDw and the adjacent pixel transistor 33 shared by the adjacent visible-light pixel PDc and the adjacent infrared-light pixel PDw with respect to the visible-light pixel PDc and the infrared-light pixel PDw. As a result, in the solid-state imaging element 1, the region of the deep trench part 230 is narrowed, and thus the dark current caused by surface roughness of the semiconductor layer 20 due to the formation of the deep trench part 230 can be suppressed.

The pixel transistor 33 is shared by four pixels adjacent in the matrix direction. As a result, the solid-state imaging element 1 can be miniaturized as compared with cases where the pixel transistor 33 is provided in each of the four pixels.

The pixel transistor 33 is shared by two adjacent pixels. As a result, the solid-state imaging element 1 can be miniaturized as compared with cases where the pixel transistor 33 is provided in each of the two pixels.

The solid-state imaging element 1 according to the present disclosure includes the semiconductor layer 20, the well contact Wlc, the penetrating pixel separation region (deep trench part 230, STI 232), and the non-penetrating pixel separation region (shallow trench part 231). In the semiconductor layer 20, the visible-light pixel PDc that receives visible light and performs photoelectric conversion, and the infrared-light pixel PDw that receives the infrared light and performs photoelectric conversion are two-dimensionally arranged. The well contact Wlc is provided in the semiconductor layer 20 and is shared by the visible-light pixel PDc and infrared-light pixel PDw adjacent to each other. The penetrating pixel separation region (deep trench part 230, STI 232) is provided in the region excluding the region corresponding to the well contact Wlc in inter-pixel region of the visible-light pixel PDc and the infrared-light pixel PDw, and penetrates the semiconductor layer 20 in the depth direction. The non-penetrating pixel separation region (shallow trench part 231) is provided in the region corresponding to the well contact Wlc in the inter-pixel region, and reaches the midway part in the depth direction from the light receiving surface of the semiconductor layer 20.

As a result, since the well contact Wlc is shared by the visible-light pixel PDc and the infrared-light pixel PDw, the solid-state imaging element 1 can be miniaturized. Furthermore, in the solid-state imaging element 1, the visible-light pixel PDc and the infrared-light pixel PDw are separated by the penetrating pixel separation region, and thus the color mixing can be suppressed.

The non-penetrating pixel separation region (shallow trench part 231) reaches, from the light receiving surface of the semiconductor layer 20, the impurity diffusion region W1 in the semiconductor layer 20 connected to the well contact Wlc. As a result, the solid-state imaging element 1 can suppress the color mixing due to leakage light from a part of the well contact Wlc.

The well contact Wlc is shared by four pixels adjacent in the matrix direction. As a result, the solid-state imaging element 1 can be miniaturized as compared with cases where the well contact Wlc is provided in each of the four pixels.

The well contact Wlc is shared by two pixels adjacent to each other. As a result, the solid-state imaging element 1 can be miniaturized as compared with cases where the well contact Wlc is provided in each of the two pixels.

The penetrating pixel separation region (deep trench part 230, STI 232) includes a trench part 230 and the element isolation structure (STI 232). The trench part (deep trench part 230) extends from the light receiving surface toward the surface opposed to the light receiving surface of the semiconductor layer. The element isolation structure (STI 232) extends from the surface opposed to the light receiving surface toward the light receiving surface and is in contact with the trench part (deep trench part 230). As a result, the solid-state imaging element 1 can more reliably shield light between the visible-light pixel PDc and the infrared-light pixel PDw by the penetrating pixel separation region (deep trench part 230, STI 232).

The non-penetrating pixel separation region (shallow trench part 231) is in contact with the penetrating pixel separation region (deep trench part 230, STI 232). As a result, in the solid-state imaging element 1, the deep trench part 230 and the shallow trench part 231 are continuous and in contact with each other in plan view, and thus, it is possible to suppress the leakage light from entering the adjacent pixel.

The non-penetrating pixel separation region (shallow trench part 231) is not in contact with the penetrating pixel separation region (deep trench part 230, STI 232). As a result, in the solid-state imaging element 1, even when a slight misalignment occurs in the process of forming the deep trench part 230 and the shallow trench part 231, the misalignment can be allowed by the space between the deep trench part 230 and the shallow trench part 231.

In the visible-light pixel PDc and the infrared-light pixel PDw, the shortest distance between the sides facing each other in plan view is 2.2 microns or less. As a result, the solid-state imaging element 1 can be sufficiently downsized while suppressing the color mixing.

A negative voltage is applied to the penetrating pixel separation region (deep trench part 230, STI 232) and the non-penetrating pixel separation region (shallow trench part 231). The solid-state imaging element 1 can suppress a defective pixel called a white spot and the dark current by recombining electrons and holes generated by the interface state and defect on the interface between the deep trench part 230 and the shallow trench part 231 and the semiconductor layer 20.

The non-penetrating pixel separation region (shallow trench part 231) is provided at the position where the visible-light pixel PDc and the infrared-light pixel PDw having a square planar shape are divided into two regions (PDc (L) and PDw (R)) having equal light receiving area and a rectangular planar shape. As a result, the solid-state imaging element 1 can increase the optical path length in the pair of visible-light pixels PDc (L) and PDc (R), and thus, the sensitivity can be improved.

<Electronic Apparatus>

Note that the present disclosure is not limited to application to the solid-state imaging element. In other words, in addition to the solid-state imaging element, the present disclosure is applicable to general electronic apparatuses employing the solid-state imaging element, such as a camera module, an imaging device, a mobile terminal device having an imaging function, or a copying machine using the solid-state imaging element in an image reading unit.

Examples of the imaging device include a digital still camera and a video camera. Examples of the mobile terminal device provided with the imaging function include a smartphone and a tablet terminal.

FIG. 41 is a block diagram illustrating a configuration example of the imaging device as an electronic apparatus 100 to which the technology according to the present disclosure is applied. The electronic apparatus 100 in FIG. 41 includes, for example, an electronic apparatus is the imaging device such as a digital still camera or a video camera, or the mobile terminal device such as a smartphone or a tablet terminal.

In FIG. 41, the electronic apparatus 100 includes a lens group 101, a solid-state imaging element 102, a DSP circuit 103, a frame memory 104, a display unit 105, a recording unit 106, an operation unit 107, and a power supply unit 108.

Furthermore, in the electronic apparatus 100, the DSP circuit 103, the frame memory 104, the display unit 105, the recording unit 106, the operation unit 107, and the power supply unit 108 are mutually connected via a bus line 109.

The lens group 101 captures incident light (image light) from a subject and forms an image on an imaging surface of the solid-state imaging element 102. The solid-state imaging element 102 corresponds to the solid-state imaging element 1 according to the above-described embodiment, and converts the amount of incident light imaged on the imaging surface by the lens group 101 into an electrical signal in units of pixels and outputs the electrical signal as a pixel signal.

The DSP circuit 103 is a camera signal processing circuit that processes a signal supplied from the solid-state imaging element 102. The frame memory 104 temporarily holds the image data processed by the DSP circuit 103 in units of frames.

The display unit 105 includes, for example, a panel type display device such as a liquid crystal panel or an organic electro luminescence (EL) panel, and displays a moving image or a still image captured by the solid-state imaging element 102. The recording unit 106 records image data of a moving image or a still image captured by the solid-state imaging element 102 on a recording medium such as a semiconductor memory or a hard disk.

The operation unit 107 issues operation commands for various functions of the electronic apparatus 100 in accordance with an operation by a user. The power supply unit 108 appropriately supplies various power sources serving as operation power sources of the DSP circuit 103, the frame memory 104, the display unit 105, the recording unit 106, and the operation unit 107 to these supply targets.

In the electronic apparatus 100 configured as described above, it is possible to suppress the occurrence of color mixing caused by the IR pixel 11IR by applying the solid-state imaging element 1 of each of the above-described embodiments as the solid-state imaging element 102.

The technical scope of the present disclosure is not limited to the above-described embodiments, and various modifications can be made without departing from the gist of the present disclosure. In addition, components of different embodiments and modifications may be appropriately combined.

Note that the effects described in the present specification are merely examples and not limited, and other effects may be provided.

Note that the present technology can also have the following configurations.

(1)

A solid-state imaging element including:

a semiconductor layer in which a visible-light pixel that receives visible light and performs photoelectric conversion and an infrared-light pixel that receives infrared light and performs photoelectric conversion are two-dimensionally arranged;

a floating diffusion region provided in the semiconductor layer and shared by the visible-light pixel and the infrared-light pixel adjacent to each other;

a penetrating pixel separation region provided in a region excluding a region corresponding to the floating diffusion region in an inter-pixel region of the visible-light pixel and the infrared-light pixel, the penetrating pixel separation region penetrating the semiconductor layer in a depth direction; and

a non-penetrating pixel separation region provided in the region corresponding to the floating diffusion region in the inter-pixel region, the non-penetrating pixel separation region reaching a midway part in the depth direction from a light receiving surface of the semiconductor layer.

(2)

The solid-state imaging element according to (1), wherein

the non-penetrating pixel separation region reaches the floating diffusion region from the light receiving surface of the semiconductor layer.

(3)

The solid-state imaging element according to (1) or (2), wherein

the floating diffusion region is shared by four pixels adjacent in a matrix direction.

(4)

The solid-state imaging element according to (1) or (2), wherein

the floating diffusion region is shared by two pixels adjacent to each other.

(5)

A solid-state imaging element including:

a semiconductor layer in which a visible-light pixel that receives visible light and performs photoelectric conversion and an infrared-light pixel that receives infrared light and performs photoelectric conversion are two-dimensionally arranged;

a pixel transistor provided in the semiconductor layer and shared by the visible-light pixel and the infrared-light pixel adjacent to each other;

a penetrating pixel separation region provided in a region excluding a region corresponding to the pixel transistor in an inter-pixel region of the visible-light pixel and the infrared-light pixel, the penetrating pixel separation region penetrating the semiconductor layer in a depth direction; and

a non-penetrating pixel separation region provided in the region corresponding to the pixel transistor in the inter-pixel region, the non-penetrating pixel separation region reaching a midway part in the depth direction from a light receiving surface of the semiconductor layer.

(6)

The solid-state imaging element according to (5), wherein

the penetrating pixel separation region is extended between the pixel transistor shared by the visible-light pixel and the infrared-light pixel and a pixel transistor shared by the visible-light pixel and the infrared-light pixel adjacent to the visible-light pixel and the infrared-light pixel.

(7)

The solid-state imaging element according to (5), wherein

the non-penetrating pixel separation region extends between the pixel transistor shared by the visible-light pixel and the infrared-light pixel and a pixel transistor shared by the visible-light pixel and the infrared-light pixel adjacent to the visible-light pixel and the infrared-light pixel.

(8)
8. The solid-state imaging element according to any one of (5) to (7), wherein

the pixel transistor is shared by four pixels adjacent in a matrix direction.

(9)

The solid-state imaging element according to any one of (5) to (7), wherein

the pixel transistor is shared by two pixels adjacent to each other.

(10)

A solid-state imaging element including:

a semiconductor layer in which a visible-light pixel that receives visible light and performs photoelectric conversion and an infrared-light pixel that receives infrared light and performs photoelectric conversion are two-dimensionally arranged;

a well contact provided in the semiconductor layer and shared by the visible-light pixel and the infrared-light pixel adjacent to each other;

a penetrating pixel separation region provided in a region excluding a region corresponding to the well contact in an inter-pixel region of the visible-light pixel and the infrared-light pixel, the penetrating pixel separation region penetrating the semiconductor layer in a depth direction; and

a non-penetrating pixel separation region provided in the region corresponding to the well contact in the inter-pixel region, the non-penetrating pixel separation region reaching a midway part in the depth direction from a light receiving surface of the semiconductor layer.

(11)

The solid-state imaging element according to (10), wherein

the non-penetrating pixel separation region reaches, from the light receiving surface of the semiconductor layer, an impurity diffusion region connected to the well contact in the semiconductor layer.

(12)

The solid-state imaging element according to (10) or (11), wherein

the well contact is shared by four pixels adjacent in a matrix direction.

(13)

The solid-state imaging element according to (10) or (11), wherein

the well contact is shared by two pixels adjacent to each other.

(14)

The solid-state imaging element according to any one of (1) to (13), wherein

the penetrating pixel separation region includes:

a trench part that extends from the light receiving surface toward a surface opposed to the light receiving surface of the semiconductor layer, and

an element isolation structure that extends from the surface opposed to the light receiving surface toward the light receiving surface, and is in contact with the trench part.

(15)

The solid-state imaging element according to any one of (1) to (14), wherein

the non-penetrating pixel separation region is in contact with the penetrating pixel separation region.

(16)

The solid-state imaging element according to any one of (1) to (14), wherein

the non-penetrating pixel separation region is not in contact with the penetrating pixel separation region.

(17)

The solid-state imaging element according to any one of (1) to (16), wherein

the visible-light pixel and the infrared-light pixel have a shortest distance of 2.2 microns or less between sides facing each other in a plan view.

(18)

The solid-state imaging element according to any one of (1) to (17), wherein

a negative voltage is applied to the penetrating pixel separation region and the non-penetrating pixel separation region.

(19)

The solid-state imaging element according to any one of (1) to (18), wherein

the non-penetrating pixel separation region is provided at a position dividing each of the visible-light pixel and the infrared-light pixel having a square planar shape into two regions having an equal light receiving area and a rectangular planar shape.

### REFERENCE SIGNS LIST

1 SOLID-STATE IMAGING ELEMENT
10 PIXEL ARRAY UNIT
11 UNIT PIXEL
11R R PIXEL
11G G PIXEL
11B B PIXEL
11IR IR PIXEL
PDc VISIBLE-LIGHT PIXEL
PDw INFRARED-LIGHT PIXEL
230 DEEP TRENCH PART
231 SHALLOW TRENCH PART
232 STI
FD FLOATING DIFFUSION REGION
Wlc WELL CONTACT
20 SEMICONDUCTOR LAYER
30 WIRING LAYER
32 WIRING
33 PIXEL TRANSISTOR
100 ELECTRONIC APPARATUS
PD PHOTODIODE

What is claimed is:

1. A solid-state imaging element comprising:
a semiconductor layer in which a visible-light pixel that receives visible light and performs photoelectric conversion and an infrared-light pixel that receives infrared light and performs photoelectric conversion are two-dimensionally arranged;
a floating diffusion region provided in the semiconductor layer and shared by the visible-light pixel and the infrared-light pixel adjacent to each other;
a penetrating pixel separation region provided in a region excluding a region corresponding to the floating diffusion region in an inter-pixel region of the visible-light pixel and the infrared-light pixel, the penetrating pixel separation region penetrating the semiconductor layer in a depth direction; and
a non-penetrating pixel separation region provided in the region corresponding to the floating diffusion region in the inter-pixel region, the non-penetrating pixel separation region reaching a midway part in the depth direction from a light receiving surface of the semiconductor layer.

2. The solid-state imaging element according to claim 1, wherein
the non-penetrating pixel separation region reaches the floating diffusion region from the light receiving surface of the semiconductor layer.

3. The solid-state imaging element according to claim 1, wherein
the floating diffusion region is shared by four pixels adjacent in a matrix direction.

4. The solid-state imaging element according to claim 1, wherein
the floating diffusion region is shared by two pixels adjacent to each other.

5. A solid-state imaging element comprising:
a semiconductor layer in which a visible-light pixel that receives visible light and performs photoelectric conversion and an infrared-light pixel that receives infrared light and performs photoelectric conversion are two-dimensionally arranged;
a pixel transistor provided in the semiconductor layer and shared by the visible-light pixel and the infrared-light pixel adjacent to each other;
a penetrating pixel separation region provided in a region excluding a region corresponding to the pixel transistor in an inter-pixel region of the visible-light pixel and the infrared-light pixel, the penetrating pixel separation region penetrating the semiconductor layer in a depth direction; and
a non-penetrating pixel separation region provided in the region corresponding to the pixel transistor in the inter-pixel region, the non-penetrating pixel separation region reaching a midway part in the depth direction from a light receiving surface of the semiconductor layer.

6. The solid-state imaging element according to claim 5, wherein
the penetrating pixel separation region is extended between the pixel transistor shared by the visible-light pixel and the infrared-light pixel and a pixel transistor shared by the visible-light pixel and the infrared-light pixel adjacent to the visible-light pixel and the infrared-light pixel.

7. The solid-state imaging element according to claim 5, wherein
the non-penetrating pixel separation region extends between the pixel transistor shared by the visible-light pixel and the infrared-light pixel and a pixel transistor shared by the visible-light pixel and the infrared-light pixel adjacent to the visible-light pixel and the infrared-light pixel.

8. The solid-state imaging element according to claim 5, wherein
the pixel transistor is shared by four pixels adjacent in a matrix direction.

9. The solid-state imaging element according to claim 5, wherein
the pixel transistor is shared by two pixels adjacent to each other.

10. A solid-state imaging element comprising:
a semiconductor layer in which a visible-light pixel that receives visible light and performs photoelectric conversion and an infrared-light pixel that receives infrared light and performs photoelectric conversion are two-dimensionally arranged;
a well contact provided in the semiconductor layer and shared by the visible-light pixel and the infrared-light pixel adjacent to each other;
a penetrating pixel separation region provided in a region excluding a region corresponding to the well contact in an inter-pixel region of the visible-light pixel and the infrared-light pixel, the penetrating pixel separation region penetrating the semiconductor layer in a depth direction; and
a non-penetrating pixel separation region provided in the region corresponding to the well contact in the inter-pixel region, the non-penetrating pixel separation region reaching a midway part in the depth direction from a light receiving surface of the semiconductor layer.

11. The solid-state imaging element according to claim 10, wherein
the non-penetrating pixel separation region reaches, from the light receiving surface of the semiconductor layer, an impurity diffusion region connected to the well contact in the semiconductor layer.

12. The solid-state imaging element according to claim 10, wherein
the well contact is shared by four pixels adjacent in a matrix direction.

13. The solid-state imaging element according to claim 10, wherein
the well contact is shared by two pixels adjacent to each other.

14. The solid-state imaging element according to claim 1, wherein
the penetrating pixel separation region includes:
a trench part that extends from the light receiving surface toward a surface opposed to the light receiving surface of the semiconductor layer, and
an element isolation structure that extends from the surface opposed to the light receiving surface toward the light receiving surface, and is in contact with the trench part.

15. The solid-state imaging element according to claim 1, wherein
the non-penetrating pixel separation region is in contact with the penetrating pixel separation region.

16. The solid-state imaging element according to claim 1, wherein
the non-penetrating pixel separation region is not in contact with the penetrating pixel separation region.

17. The solid-state imaging element according to claim 1, wherein
the visible-light pixel and the infrared-light pixel have a shortest distance of 2.2 microns or less between sides facing each other in a plan view.

18. The solid-state imaging element according to claim 1, wherein
a negative voltage is applied to the penetrating pixel separation region and the non-penetrating pixel separation region.

19. The solid-state imaging element according to claim 1, wherein
the non-penetrating pixel separation region is provided at a position dividing each of the visible-light pixel and the infrared-light pixel having a square planar shape into two regions having an equal light receiving area and a rectangular planar shape.
